(19) United States
(12) Patent Application Publication
(10) Pub. No.: US 2006/0141136 A1
(43) Pub. Date: Jun. 29, 2006

(54) System and methods for manufacturing an organic electroluminescent element

(75) Inventor: Takashi Miyazawa, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/356,139

(22) Filed: Feb. 17, 2006

Related U.S. Application Data
(62) Division of application No. 10/238,622, filed on Sep. 11, 2002.

(30) Foreign Application Priority Data
Sep. 14, 2001 (JP) 2001-279757
Sep. 10, 2002 (JP) 2002-264522

(51) Int. Cl. B05D 5/06; B05D 5/00; B05D 5/12

(52) U.S. Cl. 427/66; 427/256

(57) ABSTRACT

To provide a new method for patterning in which a degree of flexibility in selection of materials is increased and, in addition, to provide a method for manufacturing a film, a method for manufacturing an organic electroluminescent element and a method for manufacturing a color filter using the aforementioned method for patterning, and furthermore, an electro-optic apparatus and a method for manufacturing the same, and electronic equipment.

This is a divisional of application Ser. No. 10/238,622 filed Sep. 11, 2002. The entire disclosure of the prior application is hereby incorporated by reference herein in its entirety.

### BACKGROUND OF THE INVENTION 1. Field of Invention

The present invention relates to a method for patterning and a method for manufacturing a film applicable to methods for manufacturing electro-optic apparatuses used as displays, display light sources, and the like. The invention further relates to a patterning apparatus, a method for manufacturing an organic electroluminescent element, a method for manufacturing a color filter, an electro-optic apparatus and a method for manufacturing the same, an electronic apparatus and a method for manufacturing the same, and electronic equipment.

2. Description of Related Art

In recent years, regarding self-luminous displays in place of liquid crystal displays, development of organic electroluminescent elements using organic materials for luminescent layers has been accelerated. In manufacture of such an organic electroluminescent element, a method for patterning a functional material, for example, a material for forming an electroluminescent layer, into a desired pattern has been considered to be one of the especially important techniques.

As processes for forming electroluminescent layers made of organic materials in the organic electroluminescent elements, a method in which a low-molecular material is made into a film by an evaporation method, as described in Appl. Phys. Lett. 51(12), Sep. 21, 1987, p. 913, and a method in which a macromolecular material is applied by coating, as described in Appl. Phys. Lett. 71(1), Jul. 7, 1997, p. 34 are primarily known.

Regarding the technique for colorization, when low-molecular materials are used, a mask evaporation method has been performed, in which luminescent materials of different luminescent colors are evaporated and formed on the desired portions corresponding to pixels through a mask with a predetermined pattern. On the other hand, when macromolecular-based materials are used, colorization using an ink-jet method has been noted because patterning can be performed with fineness and with ease. Literatures disclosing manufacture of organic electroluminescent elements by such an ink-jet method have been known previously, for example, Japanese Unexamined Patent Application Publication Nos. 7-235378, 10-12377, 11-40358 and 11-54270.

Regarding the organic electroluminescent elements, it has been suggested that a positive hole injection layer or positive hole transport layer is formed between an anode and a luminescent layer in order to improve the luminous efficacy and durability. See, for example Japanese Unexamined Patent Application Publication No. 7-235378.

### SUMMARY OF THE INVENTION

Regarding manufacture of such an organic electroluminescent element, and the like, provision of new methods for patterning in which, especially, a degree of flexibility in selection of materials is increased has been required because of diversification of materials for various constituents, and the like.

Accordingly, the present invention provides a new method for patterning in which a degree of flexibility in selection of materials is increased and, in addition, provides a method for manufacturing a film, a method for manufacturing an organic electroluminescent element and a method for manufacturing a color filter using the aforementioned method for patterning, and furthermore, an electro-optic apparatus and a method for manufacturing the same, and electronic equipment.

In order to achieve the aforementioned objects, a method for patterning of the present invention can include the steps of placing a material layer above a first substrate, and irradiating the material layer with a light beam so as to shift a material in the material layer onto the first substrate and to form a material portion with a desired pattern.

According to this method for patterning, the material in the material layer irradiated with the light beam shifts onto the first substrate based on the principle that when a light beam is applied at high energy, a part of the irradiated material flies molecularly. Consequently, when application of the light beam is performed in accordance with a desired pattern, it becomes possible to form the material portion with a desired pattern on the first substrate with ease and with precision. The material in the material layer is not always specifically unlimited, and the flexibility in selection of the material can be increased.

In the aforementioned method for patterning, preferably, the light beam is applied to the material layer from the aforementioned first substrate side through the first substrate.

According to this, for example, since the first substrate is located on the surface side of the material layer, the surface being irradiated with the light beam, the material flied from the material layer becomes likely to shift onto the first substrate side and, therefore, the material portion can be patterned excellently onto the first substrate.

In the aforementioned method for patterning, preferably, the aforementioned material layer is arranged on a second substrate. According to this, the patterning treatment by application of the light beam can be performed by only placing the second substrate provided with the material layer on the first substrate and, therefore, simplification of the treatment can be achieved.

In the aforementioned method for patterning, preferably, the aforementioned material layer is arranged beforehand on the second substrate by patterning, and the material portion with a desired pattern is formed on the first substrate in accordance with this pattern arranged on the second substrate. According to this, for example, a plurality of materials can be patterned in one step by arranging different materials on the second substrate as material layers and, therefore, an increase in efficiency of the patterning step can be achieved.

In the aforementioned method for patterning, preferably, a mask for light irradiation formed beforehand in accordance with a desired pattern is used, and application of the light beam is performed through the mask for light irradiation so as to shift the material in the material layer onto the first substrate and to form the material portion with a desired pattern. According to this, for example, after patterning is performed with respect to one material, patterning of another material can be performed by moving the mask, or a plurality of masks can be prepared in accordance with the materials, and patterning of a plurality of materials can be performed by appropriately using these masks. Consequently, an increase in efficiency of the patterning step can be achieved.

In the aforementioned method for patterning, the aforementioned light beam is preferably a laser beam, and in that case, the laser beam is preferably a pulse beam. According to this, for example, since stable high-energy light beam can be applied, excellent patterning can be performed. Since the laser beam has superior rectilinear movement property (coherency), a precise pattern can be formed. Here, the laser beam not only refers to light generated by laser oscillation, but also includes light generated as a result of harmonic generation or wavelength conversion.

In the case where the laser beam is a pulse beam, when the pulse width is decreased, it becomes possible that a material can be allowed to absorb light based on a non-linear optical effect even without linear absorption. Consequently, when the material layer is irradiated with a pulse beam through the substrate, even if linear absorption is exist in the substrate, it becomes possible to allow the aforementioned material layer to nearly selectively absorb the light by appropriately setting the focal length of the light beam with lenses, and the like.

In the aforementioned method for patterning, preferably, a non-linear optical phenomenon of the aforementioned material in the aforementioned material layer is induced by application of the aforementioned light beam to the aforementioned material layer so as to shift the aforementioned material onto the aforementioned first substrate.

When the non-linear optical effect is used as described above, since the probability of occurrence of phenomena (non-linear optical phenomena) induced by the non-linear optical effect becomes larger than the first power of the pulse intensity (wattage on a unit area basis), by making the pulse intensity in the material layer larger adequately than that in the layer other than the material layer, through which the pulse beam passes, the probability of occurrence of phenomena in the material layer can be made larger adequately than the probability of occurrence in the portion other than the material layer, through which the pulse beam passes. Furthermore, when a higher-order non-linear optical effect is used, it becomes possible to increase further remarkably the probability of occurrence of phenomena at a desired position compared with the probability of occurrence at a position other than the desired position.

In the aforementioned method for patterning, sometimes, the aforementioned material layer is preferably an electrode material.

According to this, for example, in the case where a pixel electrode (anode) of the organic electroluminescent element is manufactured from ITO, although other metal wirings on the element are adversely affected by corrosion, etc., when this is conventionally patterned by etching with a strong acid, since patterning can be performed without use of a strong acid by the present method, the aforementioned inconveniences can be avoided.

In the aforementioned method for patterning, preferably, the aforementioned material layer is a material for forming at least one of an electron transport layer, a positive hole transport layer, and a luminescent layer constituting the organic electroluminescent element.

According to this, the electron transport layer, the positive hole transport layer, or the luminescent layer can be formed with ease and with precision and, furthermore, it becomes possible to select the material for formation thereof with a high degree of flexibility.

The aforementioned method for patterning preferably includes the steps of forming a reception layer as the uppermost layer of the aforementioned first substrate, placing an optical material layer containing an optical material on the aforementioned reception layer, and irradiating the aforementioned optical material layer with a light beam so as to shift the aforementioned optical material into the aforementioned reception layer. According to this, the optical material can be shifted into the reception layer without specific limitation and, therefore, the flexibility in selection of the optical material can be increased.

A method for manufacturing a film of the present invention includes the steps of placing a material film above a first substrate, irradiating partially the material film with a light beam, and shifting a material in the portion irradiated with the aforementioned light beam of the material film onto the first substrate. According to this method for manufacturing a film, it becomes possible to shift the material onto the first substrate with ease. The material in the material film is not always specifically unlimited, and the flexibility in selection of the material can be increased.

Another method for manufacturing a film of the present invention includes the steps of placing a material film provided with a predetermined pattern above a first substrate, irradiating the aforementioned material film with a light beam so as to shift a material in the aforementioned material film onto the aforementioned first substrate. According to this method for manufacturing a film, it becomes possible to shift the material in the material film onto the first substrate in the condition of being in accordance with the predetermined pattern of the material film. The material in the material film is not always specifically unlimited, and the flexibility in selection of the material can be increased.

A patterning apparatus of the present invention is for forming a material portion with a desired pattern by irradiating a material layer with a light beam so as to shift a material in the material layer onto a substrate, and the patterning apparatus is provided with a light irradiation mechanism for applying the aforementioned light beam and a holding mechanism for holding the aforementioned substrate. According to this patterning apparatus, when the material layer is irradiated with the light beam by the light irradiation mechanism, the material in the material layer can be shifted onto the substrate held by the holding mechanism based on the principle that when a light beam is applied at high energy, a part of the irradiated material flies molecularly. Consequently, when application of the light beam is performed in accordance with a desired pattern, it becomes possible to form the material portion with a desired pattern on the substrate with ease and with precision. The material in the material layer is not always specifically unlimited, and the flexibility in selection of the material can be increased.

In the aforementioned patterning apparatus, preferably, the aforementioned light irradiation mechanism is provided with a scanning portion for scanning a position to be irradiated with the light beam. According to this, even when the substrate is fixed to the holding device, it becomes possible to form the material portion with a desired pattern on the substrate with ease and with precision by scanning the position to be irradiated with the light beam.

The aforementioned patterning apparatus is preferably provided with a mask for light irradiation in order to selectively irradiate the substrate with the light beam applied from the aforementioned light irradiation mechanism. According to this, even when the substrate is fixed to the holding device, the substrate can be selectively irradiated with the light beam applied from the aforementioned light irradiation mechanism by using the mask for light irradiation and, therefore, it becomes possible to form the material portion with a desired pattern on the substrate with ease and with precision.

A method for manufacturing an organic electroluminescent element of the present invention can include the step of forming at least one of an electron transport layer, a positive hole transport layer, and a luminescent layer by using the aforementioned method for patterning. According to this method for manufacture, since the electron transport layer, the positive hole transport layer, or the luminescent layer can be formed with ease and with precision and, furthermore, the material for formation thereof can be selected with a high degree of flexibility, improvement of the quality of the resulting organic electroluminescent element and reduction of the cost can be achieved.

A method for manufacturing a color filter of the present invention can include the steps of forming a material layer from a color filter material, and patterning the color filter using the aforementioned method for patterning or the aforementioned patterning apparatus. According to this method for manufacture, since the color filter can be formed with ease and with precision and, furthermore, the material for formation thereof can be selected with a high degree of flexibility, improvement of the quality of the resulting color filter and reduction of the cost can be achieved.

A method for manufacturing an electro-optic apparatus of the present invention can include the step of patterning at least a part of constituents by using the aforementioned method for patterning, the method for manufacturing a color filter, or the aforementioned patterning apparatus. According to this method for manufacture, since the material portion with a desired pattern or the color filter can be formed with ease and with precision and, furthermore, the materials for formation thereof can be selected with a high degree of flexibility, improvement of the quality of the resulting material portion and color filter and, in addition, reduction of the cost can be achieved.

Another method for manufacturing an electro-optic apparatus of the present invention can include the steps of forming beforehand a host material among materials for forming a luminescent layer constituting an organic electroluminescent element on a first substrate with a desired pattern and, thereafter, shifting a guest material among the materials for forming the aforementioned luminescent layer into the pattern made of the aforementioned host material by using the aforementioned method for patterning or the aforementioned patterning apparatus so as to form the luminescent layer provided with the host material including the guest material.

According to this method for manufacture, since the guest materials corresponding to, for example, red, blue, and green, are separately shifted onto the respective desired positions in the pattern made of the host material, the pattern being formed beforehand, the luminescent layer which has a desired pattern and which exhibits desired colors can be formed with ease and with precision.

An electro-optic apparatus of the present invention is produced by the aforementioned method for manufacturing an electro-optic apparatus. According to this electro-optic apparatus, improvement of the quality of the resulting material portion and color filter and, furthermore, reduction of the cost can be achieved, or the luminescent layer which has a desired pattern and which exhibits desired colors can be formed with ease and with precision.

A method for manufacturing an electronic apparatus of the present invention can include the step of patterning at least a part of constituents by using the aforementioned method for patterning or the aforementioned patterning apparatus. According to this method for manufacturing an electronic apparatus, since the constituents can be formed with ease and with precision and, furthermore, the materials for formation thereof can be selected with a high degree of flexibility, improvement of the quality of the resulting electronic apparatus and reduction of the cost can be achieved.

In an electronic apparatus of the present invention, at least a part of constituents has been patterned by the aforementioned method for patterning or the aforementioned patterning apparatus. According to this electronic apparatus, since the constituents have been formed with ease and with precision and, furthermore, formation has been performed while the materials for formation thereof have been selected with a high degree of flexibility, improvement of the quality and reduction of the cost have been achieved.

Electronic equipment of the present invention can be provided with the aforementioned electro-optic apparatus as a display device. In this electronic equipment as well, regarding, especially, the display device thereof, improvement of the quality of the material portion and the color filter produced as described above and, furthermore, reduction of the cost have been achieved, or the luminescent layer which has a desired pattern and which exhibits desired colors is arranged with ease and with precision.

### BRIEF DESCRIPTION OF THE DRAWINGS

The invention will be described with reference to the accompanying drawings, wherein like numerals reference like elements, and wherein:

FIG. 1 is a schematic configuration diagram of an example of the patterning apparatus of the present invention;

FIG. 2 is a schematic configuration diagram of another example of the patterning apparatus of the present invention;

FIG. 3 is a circuit diagram showing the arrangement portion of an electro-optic apparatus of the present invention;

FIG. 4 is a plan view showing a two-dimensional structure of the pixel portion in the electro-optic apparatus shown in FIG. 3 under magnification;

FIGS. 5(a) to (e) are sectional views of the key portion side for illustrating step by step the first example in which the method for patterning of the present invention is applied to the method for manufacturing the electro-optic apparatus shown in FIG. 3 and FIG. 4;

FIGS. 6(a) to (c) are sectional views of the key portion side for illustrating step by step the method for patterning of the present invention;

FIGS. 7(a) to (c) are sectional views of the key portion side for illustrating steps following FIG. 5;

FIGS. 8(a) and (b) are sectional views of the key portion side for illustrating steps following FIG. 7;

FIG. 9 is for illustrating step by step the second example in which the method for patterning of the present invention is applied to the method for manufacturing the electro-optic apparatus shown in FIG. 3 and FIG. 4, and (a) is a plan view of the key portion of the second substrate, (b) is a sectional view of the key portion side of the second substrate different from that shown in (a), and (c) is a sectional view of the key portion side showing the condition of the second substrate shown in (b) being arranged on the transparent substrate;

FIG. 10 is a diagram for illustrating the schematic configuration of an ink-jet head, (a) is a perspective view of the key portion, and (b) is a sectional view of the key portion side;

FIGS. 11(a) and (b) are plan views of the key portion for illustrating masks for light irradiation used for the present invention;

FIGS. 12(a) and (b) are sectional views of the key portion side for illustrating the method in which patterning is performed while host/guest materials are separately implanted in sequence; and

FIG. 13 is a diagram showing specific examples of electronic equipment provided with the electroluminescent display, and (a) is a perspective view showing an example of application to a cellular phone, (b) is a perspective view showing an example of application to an information processing apparatus, and (c) is a perspective view showing an example of application to a wristwatch type electronic equipment.

### DETAILED DESCRIPTION OF PREFERRED EMBODIMENTS

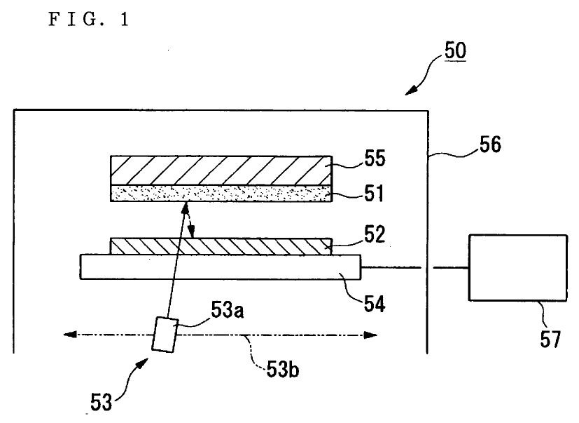

The present invention will be described below in detail. FIG. 1 is a diagram showing an example of the patterning apparatus of the present invention, and reference numeral 50 in FIG. 1 denotes the patterning apparatus. This patterning apparatus 50 is for irradiating a material layer 51 with a light beam so as to shift a material in this material layer 51 onto a substrate 52 and to form a material portion with a desired pattern on the substrate 52, and has a configuration provided with a light irradiation mechanism 53 for applying the aforementioned light beam and a holding mechanism 54 for holding the aforementioned substrate 52.

The aforementioned material layer 51 is arranged on the surface of a second substrate 55 by, for example, film formation on the surface of the second substrate 55, as shown in FIG. 1, or being held mechanically. The second substrate 55 is arranged and fixed in a chamber 56 with an appropriate jig (not shown in the drawing), etc., and, therefore, the material layer 51 itself is also arranged and fixed in the chamber 56. The chamber 56 is connected to a decompression device (not shown in the drawing), for example, a vacuum pump and, thereby, the inside of the chamber can be adjusted to be a desired reduced pressure atmosphere (including a high vacuum atmosphere). The chamber 56 and the second substrate 55 are provided with respective heaters (not shown in the drawing,) and, thereby, the inside of the chamber 56 and the material layer 51 on the surface of the second substrate 55 can be heated to desired temperatures.

It should be understood that the material for forming the aforementioned material layer 51 is not specifically limited, and arbitrary materials can be used in accordance with constituents targeted for formation. Examples of usable single metals include, for example, iron, nickel, gold, silver, manganese, and cobalt. Examples of usable alloys include, for example, nickel-iron, iron-manganese, cobalt-iron, and iridium-manganese. Examples of usable dielectrics include, for example, silicic acid compounds, e.g., K₂SiO₃, Li₂SiO₃, CaSiO₃, ZrSiO₄, and Na₂SiO₃, titanium oxides, e.g., TiO, Ti₂O₃, and TiO₂, titanic acid compounds, e.g., BaTiO₄, BaTiO₃, Ba₂Ti₉O₂O, BaTi₅O₁₁, CaTiO₃, SrTiO₃, PbTiO₃, MgTiO₃, ZrTiO₂, SnTiO₄, Al₂TiO₅, and FeTiO₃, zircon oxides, e.g., zirconium oxide (ZrO₂), BaZrO₃, ZrSiO₄, PbZrO₃, MgZrO₃, and K₂ZrO₃, and furthermore, PZT [Pb(Zr,Ti)O₃], PLZT [(Pb,La)(Zr,Ti)O₃], SBT [Sr(Bi,Ta)O], and SBN [Sr(Bi,Nb)O].

As the material for forming the material layer 51, organic materials, for example, polyfluorene and derivatives thereof, polyphenylene vinylene and derivatives thereof, and furthermore, various coloring matters, can be used. Biological materials, for example, proteins, can also be used. When the biological materials, for example, proteins, are used as the material for the material layer 51, for example, this may be mixed with an appropriate solvent, and this may be dried on a sample plate so as to produce the material layer 51.

In the chamber 56, the holding mechanism 54 for holding the substrate 52 to become a target for patterning is arranged. Since a light beam is applied from the substrate 52 side as described later in the present example, this holding mechanism 54 is composed of a translucent (transparent) stage made of glass, etc., as shown in FIG. 1. It should be understood that this holding mechanism 54 is not specifically limited as long as it can hold the substrate 52, and various types can be used. For example, a ring-shaped holder supporting only the periphery of the substrate 52 in order that the light beam can be applied from the substrate 52 side, a plurality of block-shaped holders supporting only a plurality of corners, a holder holding the substrate 52 by sandwiching the side surfaces of the substrate 52 therein, or the like can be used.

Such a holding mechanism 54 is connected to a movement mechanism 57 which allows the substrate 52 held by this to move in the horizontal direction and the vertical direction by moving this. The substrate 54 held by the holding mechanism 54 under such a configuration is arranged in order to face the aforementioned material layer 51 and to become in the condition of being close adequately to this. The movement mechanism 57 may be configured to allow movement only in any one of the horizontal direction and the vertical direction. However, in that case as well, regarding the configuration, it is preferable that when the substrate 54 held by the holding mechanism 54 faces the material layer 51, the surface of the substrate 54 is brought close adequately to the surface of the material layer 51. In FIG. 1, although the surface of the substrate 54 and the surface of the material layer 51 are shown with some distance therebetween, this is for convenience of later descriptions. In practice, the surface of the substrate 54 and the surface of the material layer 51 are specified to be close adequately to each other with a slight gap therebetween.

The light irradiation mechanism 53 can be arranged in the chamber 56 or is arranged outside the chamber 56, and is provided with a light source 53a for applying the light beam. In the present example, a scanning portion 53b for scanning a position to be irradiated with the light beam applied from the light source 53a is further provided. The light source 53a is chosen beforehand in order to apply a light beam having a wavelength and intensity capable of passing through the substrate 52, etc., and being applied to the aforementioned material layer 51, and is subjected to use. The energy intensity thereof is also adjusted beforehand in order that a part of the material in the irradiated material layer 51 flies molecularly, shifts onto the side of the surface from which the light beam is applied, that is, the substrate 52 side, and diffuse. As the light beam having such energy intensity, although light beams from stationary light sources, for example, a mercury lamp light beam, halogen lamp light beam, and xenon lamp light beam, can be used, a laser beam is used most suitably. Examples of suitably used laser beams include, for example, an excimer laser, Nd:YAG laser, titanium sapphire laser, and harmonics of these laser beams, and a light beam generated by parametric wavelength conversion.

When the laser beam is thus adopted as the light beam, this is preferably a pulse beam, and in that case, the pulse width is desirably 20 ns or less, more desirably, is 200 ps or less, and further desirably, is 200 fs or less. The reason is as described below. When the pulse width is decreased, it becomes possible to allow a substance to absorb light based on the non-linear optical effect even without linear absorption. Consequently, by using the non-linear optical effect, when the material layer is irradiated with a pulse beam having been allowed to pass through the substrate, even if the substrate exhibits linear absorption, the aforementioned material layer can be allowed to nearly selectively absorb the light by appropriately setting the focal distance of the light beam with a lens, etc.

Examples of non-linear optical responses include, for example, generation of a harmonic, the Pockels effect, the Kerr effect, and multiphoton absorption, e.g., two-photon absorption. Among them, the multiphoton absorption is used preferably.

For example, in the case where the light irradiation mechanism 53 is arranged outside the chamber 56, by combining optical components (not shown in the drawing), for example, prisms and lenses, with respect to the light source 53a thereof, the optical path thereof and the focal distance may be adjusted appropriately on as needed basis.

In order to form the material portion with a desired pattern on the substrate 52 by the patterning apparatus 50 having such a configuration, initially, the second substrate 55 having the material layer 51 corresponding to the material portion of the pattern to be formed is placed and fixed at a predetermined position. Subsequently, the substrate 52 is held and fixed to the holding mechanism 54 and, furthermore, the movement mechanism 57 is driven to adjust the substrate 52 at the position facing the aforementioned material layer 51.

If necessary, the inside of the chamber 56 and/or the second substrate 55 is heated to a desired temperature and, in addition, the inside of the chamber 56 is decompressed. The pressure in the chamber 56 is not specifically limited, and, may be, for example, atmospheric pressure and vacuum atmosphere, or as a matter of course, may be reduced pressure atmosphere within the range between them.

Thereafter, the light beam is applied from the light source 53a of the light irradiation mechanism 53 to the surface portion of the material layer 51 as indicated by a solid line shown in FIG. 1. Such irradiation onto the material layer 51 surface portion is allowed to pass through the substrate 52 and reach the material layer 51 surface portion by adjusting appropriately the sort of the light beam and the energy intensity and wavelength thereof, and thereby bringing about a non-linear optical effect.

Then, since the irradiated portion of the material layer 51 flies molecularly, the material in this material layer 51 shifts onto the predetermined position of the substrate 52 indicated by a broken line shown in FIG. 1 and diffuses and, thereby, the material in the material layer 51 deposits onto the predetermined position of the substrate 52. Consequently, the pattern to become the material portion in the present invention can be formed on the substrate 52 by scanning the position to be irradiated with the light beam applied from the light source 53a with the scanning portion 53b, and by allowing the position to be irradiated to correspond to the pattern.

Although the optical path of the light beam from the light source 53 is drawn on the skew with respect to the material layer 51 in FIG. 1, this is for convenience of illustrating shift and diffusion of the material from the material layer 51. As a matter course, the light beam may be applied perpendicularly to the material layer 51.

In such a patterning apparatus 50, the material portion with a desired pattern can be formed on the substrate 52 with ease and with precision by performing application of the light beam by the light irradiation mechanism 53 in accordance with a desired pattern. Since the material in the material layer 51 is not specifically limited, the degree of flexibility in selection of the material can be increased.

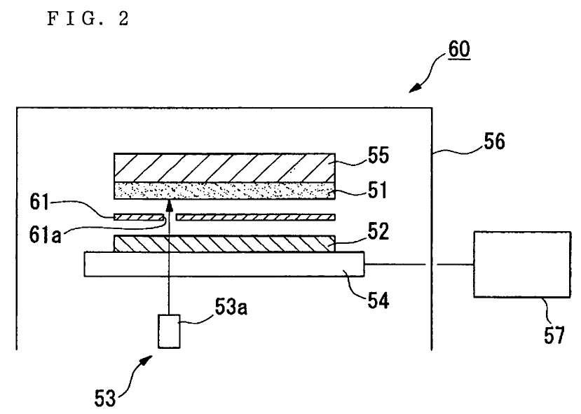

FIG. 2 is a diagram showing another example of the patterning apparatus of the present invention, and reference numeral 60 in FIG. 2 denotes the patterning apparatus. This patterning apparatus 60 is different from the patterning apparatus 50 shown in FIG. 1 in that a mask 61 for light irradiation to selectively apply a light beam to the substrate 52 is arranged instead of arrangement of the scanning portion 53b for scanning the position to be irradiated with the light beam in the light irradiation mechanism 53.

That is, in the patterning apparatus 60 of the present example, the mask 61 for light irradiation is arranged between the substrate 52 held on the holding mechanism 54 and the material layer 51. This mask 61 for light irradiation is composed of a metal, etc., having at least one opening 61a at an appropriate position, and is configured to pass the light beam through the aforementioned opening 61a and to interrupt the light beam at the portion other than the opening 61a. The opening 61a is formed in accordance with the shape of a desired pattern.

The mask 61 for light irradiation is fixed to the substrate 52 or the holding mechanism 54 holding this by, for example, a magnet or other mechanical fixing device.

Although the mask 61 for light irradiation is arranged between the material layer 51 and the substrate 52 in FIG. 2, the mask may be arranged between the substrate 52 and the holding mechanism 54, or be arranged under the holding mechanism 54.

In order to form the material portion with a desired pattern on the substrate 52 by the patterning apparatus 60 having such a configuration, initially, in a manner similar to that in the aforementioned example, the second substrate 55 having the material layer 51 is placed and fixed at a predetermined position. Subsequently, the substrate 52 is held and fixed to the holding mechanism 54 and, furthermore, the mask 61 for light irradiation is set at a desired position relative to the substrate 52. Under that condition, these are moved to a predetermined position relative to the material layer 51.

Furthermore, if necessary, the inside of the chamber 56 and/or the second substrate 55 is set at a desired temperature and, in addition, the inside of the chamber 56 is decompressed. This treatment may also be performed at room temperature and atmospheric pressure without specific adjustment of the temperature, the degree of decompression, and the like. However, when the mask 61 for light irradiation brings about expansion and contraction depending on the temperature, preferably, the temperature is adjusted appropriately so as to suppress this.

Thereafter, the light beam is applied from the light source 53a of the light irradiation mechanism 53, and is allowed to pass through the opening 61a of the mask 61 for light irradiation and to reach the surface portion of the material layer 51 as indicated by a solid line shown in FIG. 2.

Then, in a manner similar to that in the aforementioned example, the irradiated portion of the material layer 51 flies molecularly and, therefore, the material in this material layer 51 shifts onto the substrate 52 side and diffuses. At this time, since the mask 61 for light irradiation is arranged between the material layer 51 and the substrate 52, the diffused material selectively passes through only the opening 61a, and is interrupted at the other portions. Consequently, the pattern to become the material portion in the present invention can be formed on the substrate 52 by allowing the position to be irradiated with the light beam applied from the light source 53a to correspond the opening 61a.

In such a patterning apparatus 60, the material portion with a desired pattern can be formed on the substrate 52 with ease and with precision by the mask 61 for light irradiation being arranged. Since the material in the material layer 51 is not specifically limited, the degree of flexibility in selection of the material can be increased.

It should be understood that the patterning apparatus of the present invention is not limited to the examples shown in FIG. 1 and FIG. 2, and various modes can be adopted. For example, both of the scanning portion 53b for scanning a position to be irradiated with the light beam applied from the light source 53a and the mask 61 for light irradiation may be arranged.

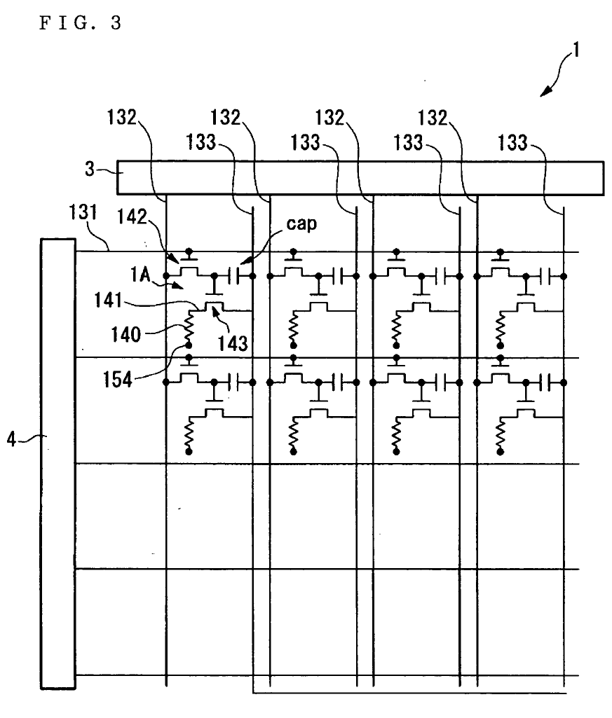

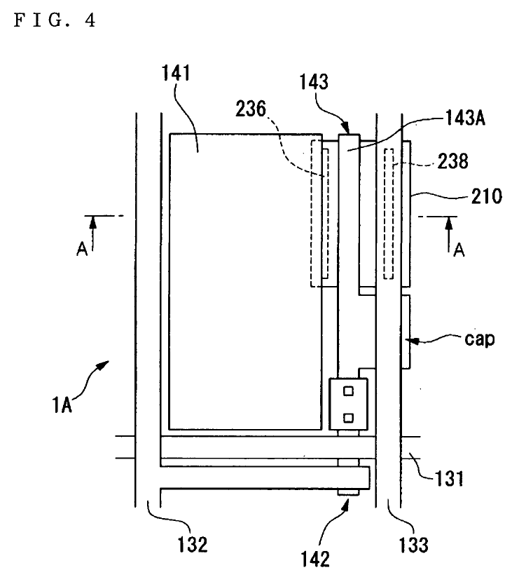

Next, a method for patterning of the present invention using the aforementioned patterning apparatus will be described based on an example in which the method is applied to manufacture of a display device (electro-optic apparatus) of active matrix type using an organic electroluminescent element. However, in advance thereof, a rough configuration of an electro-optic apparatus produced by this manufacture will be described with reference to FIG. 3 and FIG. 4.

In FIG. 3 and FIG. 4, reference numeral 1 denotes a display device. As shown in a circuit diagram, FIG. 3, this display device 1 has a configuration in which respective wirings of a plurality of scanning lines 131, a plurality of signal lines 132 extending in the direction intersecting these scanning lines 131, and common feeder lines 133 extending parallel to these signal lines 132 are arranged on a transparent substrate, and pixels (pixel region elements) 1A are arranged on an intersection of the scanning line 131 and the signal line 132 basis.

With respect to the signal lines 132, a data side driving circuit 3 provided with a shift resister, a level shifter, a video line, and an analog switch is arranged.

On the other hand, with respect to the scanning lines 131, a scanning side driving circuit 4 provided with a shift resister and a level shifter is arranged. In each of the pixel regions 1A, a first thin film transistor 142 in which scanning signals are supplied to a gate electrode through the scanning line 131, a retention volume cap which retains image signals supplied from the signal line 132 through this first thin film transistor 142, a second thin film transistor 143 in which the image signals retained by the retention volume cap are supplied to a gate electrode, a pixel electrode 141 into which driving circuit is fed from the common feeder line 133 when electrically connected to the common feeder line 133 through this second thin film transistor 143, and a luminescent portion 140 held between this pixel electrode 141 and a counter electrode 154 are arranged.

Under such a configuration, when the scanning line 131 is driven and the first thin film transistor 142 is turned on, the voltage of the signal line 132 at that time is retained by the retention volume cap, and the conduction condition of the second thin film transistor 143 is determined in accordance with the condition of the retention volume cap. Subsequently, a current passes from the common feeder line 133 to the pixel electrode 141 through the channel of the second thin film transistor 143 and furthermore, a current passes to the counter electrode 154 through the luminescent element 140. Consequently, the luminescent portion 140 emits light in accordance with the quantity of the current passed thereto.

As shown in FIG. 4 which is a plan view under magnification in the condition that the counter electrode and the organic electroluminescent element are removed, the two-dimensional structure of each pixel 1A has an arrangement in which four sides of the pixel electrode 141 having a rectangular two-dimensional shape are surrounded by the signal line 132, the common feeder line 133, the scanning line 131, and a scanning line for other pixel electrode, although not shown in the drawing.

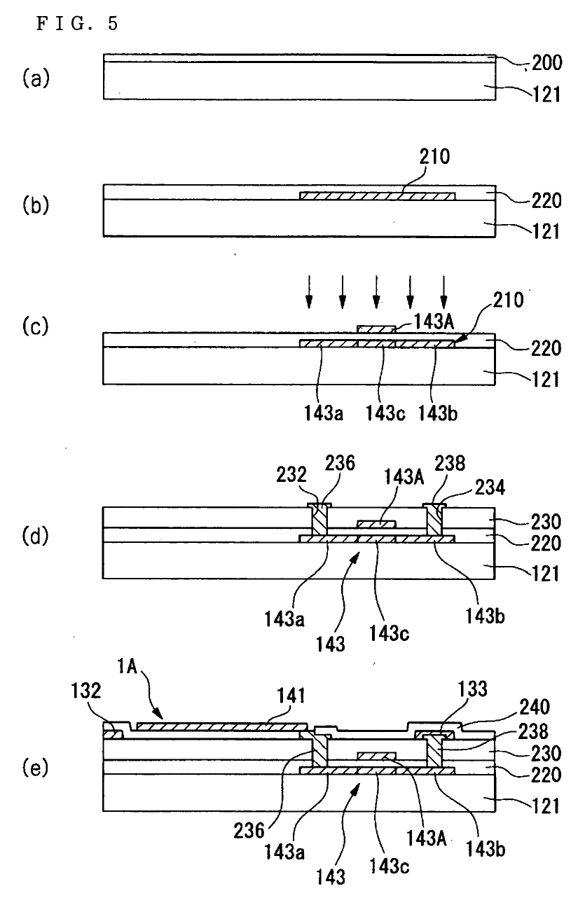

Next, a first example of the case where the method for patterning of the present invention or the method for manufacturing a film of the present invention is applied as a method for manufacturing an organic electroluminescent element used for such a display device 1 will be described with reference to FIG. 5 to FIG. 8. In FIG. 5 to FIG. 8, it should be understood that only a single pixel 1A is illustrated in order to simplify the description.

A substrate to become a base portion of a first substrate in the present invention is prepared. Regarding an organic electroluminescent element, emitted light by a luminescent layer described later can be taken out from the substrate side, and can also be configured to take out from the side opposite to the substrate. Regarding the configuration in which the emitted light is taken out from the substrate side, as the material for the substrate, although transparent or translucent materials, for example, glass, quartz, and resin, are used, especially, inexpensive soda glass can also be suitably used. When the soda glass is used, a silica coat is preferably applied thereto because an effect of protecting soda glass susceptible to the acid or alkali is exhibited and, in addition, an effect of improving the flatness of the substrate is also exhibited.

The emission color may be controlled by placing a color conversion film including a color filter film or a luminescent material or a dielectric reflection film on the substrate.

Regarding the configuration in which the emitted light is taken out from the side opposite to the substrate, the substrate may be opaque, and in that case, ceramics, for example, alumina, metal sheets of, for example, stainless steel, having been subjected to an insulation treatment, for example, surface oxidation, thermosetting resins, thermoplastic resins, and the like can be used.

In this example, as shown in FIG. 5(a), a transparent substrate 121 made of soda glass, and the like, is prepared as a substrate. With respect to this, if necessary, a substrate protection film (not shown in the drawing) made of silicon oxide film of about 200 to 500 nm in thickness is formed by a plasma CVD method using TEOS (tetraethoxysilane), oxygen gas, and the like, as materials.

The temperature of the transparent substrate 121 is set at about 350° C., and a semiconductor film 200 made of an amorphous silicon film of about 30 to 70 nm in thickness is formed by a plasma CVD method on the surface of the substrate protection film. Subsequently, a crystallization step of a laser annealing method, a solid phase growth method, or the like is performed with respect to this semiconductor film 200 and, therefore, the semiconductor film 200 is crystallized to a polysilicon film. In the laser annealing method, for example, a line beam of 400 mm in major axis from an excimer laser is used, and the output intensity thereof is specified to be, for example, 200 mJ/cm². Regarding the line beam, the line beam is scanned in order that the portions corresponding to 90% of the peak value of the laser intensity in the minor axis direction overlap on a region basis.

As shown in FIG. 5(b), the semiconductor film (polysilicon film) 200 is patterned so as to produce an island-shaped semiconductor film 210, and with respect to the surface thereof, a gate insulation film 220 made of a silicon oxide film or nitride film of about 60 to 150 nm in thickness is formed by a plasma CVD method using TEOS, oxygen gas, etc., as materials. The semiconductor film 210 is to become a channel region and a source and drain region of the second thin film transistor 143 shown in FIG. 3, and at different sectional positions, a semiconductor film to become a channel region and a source and drain region of the first thin film transistor 142 is also formed. That is, in the manufacturing steps shown in FIG. 5 to FIG. 8, two sorts of transistors 142 and 143 are produced simultaneously. However, since the manufacturing procedures are the same, in the following description, regarding the transistors, only the second thin film transistor 143 will be explained, and the explanation of the first thin film transistor 142 is omitted.

As shown in FIG. 5(c), a conductive film containing metals, for example, aluminum, tantalum, molybdenum, titanium, and tungsten, is formed by a sputtering method and, thereafter, this is patterned so as to form a gate electrode 143A.

Under this condition, phosphorus ions are implanted at a high concentration and, therefore, source and drain regions 143a and 143b are formed in the semiconductor film 210 based on self align with respect to the gate electrode 143A. The portion into which no impurity has been introduced becomes a channel region 143c.

As shown in FIG. 5(d), after an interlayer insulation film 230 is formed, contact holes 232 and 234 are formed, and relay electrodes 236 and 238 are embedded in those contact holes 232 and 234.

As shown in FIG. 5(e), the signal line 132, the common feeder line 133, and the scanning lines (not shown in FIG. 5) are formed on the interlayer insulation film 230. At this time, since the portion surrounded by them becomes a pixel for forming a luminescent layer, etc., as described later, each wiring is formed in order that the second thin film transistor 143 is not located directly below the portion surrounded by the aforementioned each wiring.

An interlayer insulation film 240 is formed covering as well as the top surface of each wiring, a contact hole (not shown in the drawing) is formed at the position corresponding to the relay electrode 236, and a conductive material, for example, ITO, is embedded in the contact hole.

Subsequently, a transparent electrode material, for example, ITO, is patterned at the position to become the pixel 1A, that is, the portion surrounded by the signal line 132, the common feeder line 133, and the scanning lines, while being connected to the conductive material in this contact hole by using the method for patterning of the present invention and, therefore, the pixel electrode 141 is formed.

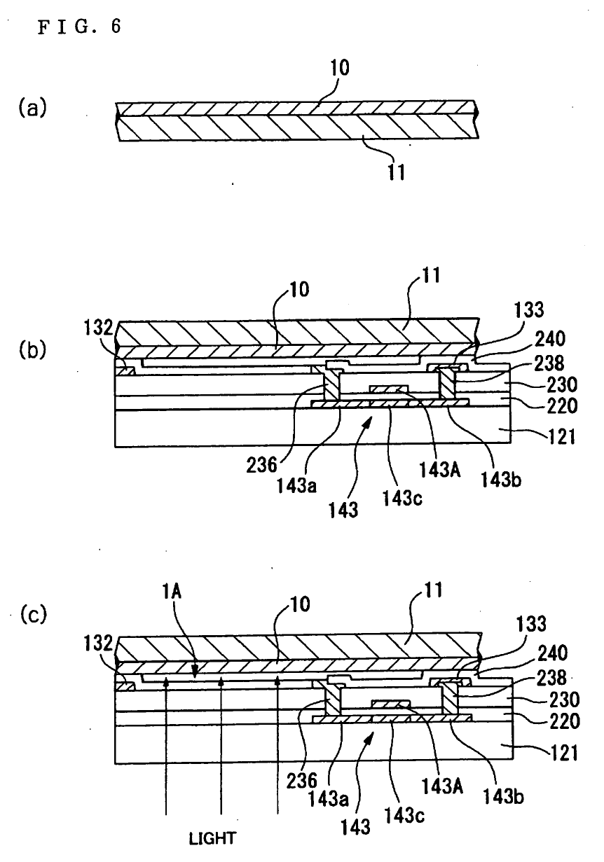

Before formation of this pixel electrode 141, as shown in FIG. 6(a), the one in which a material layer 10 composed of SnO₂ doped with ITO or fluorine, and furthermore, a transparent electrode material, for example, ZnO and polyaniline, is arranged on a second substrate 11 is prepared in advance. As the second substrate 11 made of, for example, a film of synthetic resin, etc., polyethylene terephthalate film on the order of 0.1 mm in thickness is used, for example. Regarding formation of this material layer 10, for example, a dipping method, a spin coating method, an ink-jet method, and an evaporation method are adopted suitably.

Subsequently, the second substrate 11 thus prepared is arranged with the material layer 10 inside, as shown in FIG. 6(b), on the surface, that is, on the side provided with the signal line 132, the common feeder line 133, and the scanning lines (not shown in FIG. 5), of the transparent substrate 121 in the condition that the conductive material is embedded in the aforementioned contact hole.

As shown in FIG. 6(c), a light beam is applied from the reverse surface side of the transparent substrate 121, that is, the side opposite to the second substrate 11, and this light beam is applied to the surface of the material layer 10 facing the portion to become the aforementioned pixel 1A. Regarding this light beam, preferably, the wavelength and the intensity thereof have been chosen in order to pass through the transparent substrate 121, the gate insulation film 220, the interlayer insulation film 230, etc., and to irradiate the aforementioned material layer 10 and, in addition, the energy intensity thereof has been adjusted beforehand in order that a part of the material of the irradiated material layer 10 flies molecularly, shifts onto the side of the surface from which the light is applied, that is, the transparent substrate 121 (transparent substrate) side, and diffuses. As the light beam having such energy intensity, although light beams from stationary light sources, for example, a mercury lamp light beam, a halogen lamp light beam, and a xenon lamp light beam, can be used, a laser beam is used most suitably. Examples of suitably used laser beams include, for example, an excimer laser, Nd:YAG laser, titanium sapphire laser, and harmonics of these laser beams, and a light beam generated by parametric wavelength conversion.

When the light beam having high energy is thus applied, the light beam passes through the transparent substrate 121, the gate insulation film 220, the interlayer insulation film 230, etc., and the aforementioned material layer 10 is irradiated. Then, since the irradiated portion of the material layer 10 flies molecularly, the material in this material layer 10 shifts onto the portion to become the aforementioned pixel 1A and diffuses and, thereby, the material for formation in the material layer 10 deposits onto the portion to become the pixel 1A. Consequently, by performing application of the light beam in accordance with the desired pattern of the pixel electrode, the pixel electrode 141 to become the material portion in the present invention can be formed as shown in FIG. 5(e). The film thickness of the pixel electrode 141 is controlled to become an appropriate thickness by adjusting, for example, the application time of the light beam. Furthermore, for example, the film thickness may be controlled to become an optimum thickness (appropriate thickness) by using a quartz type film thickness monitor, or by monitoring spectroscopic data, e.g., emission intensity and light absorption intensity.

Embedding of the conductive material in the aforementioned contact hole can be performed using the method for patterning shown in FIG. 6. That is, when the conductive material is embedded in the contact holes and, therefore, the relay electrodes 236 and 238 are formed, the aforementioned second substrate 11 is arranged above the opening portions of these contact holes, and the material layer 10 thereof is allowed to face toward the contact hole side. Subsequently, the material layer 10 is irradiated with a high-energy light beam as described above, the material in the material layer 10 is shifted into the contact holes and, therefore, the relay electrodes 236 and 238 are formed.

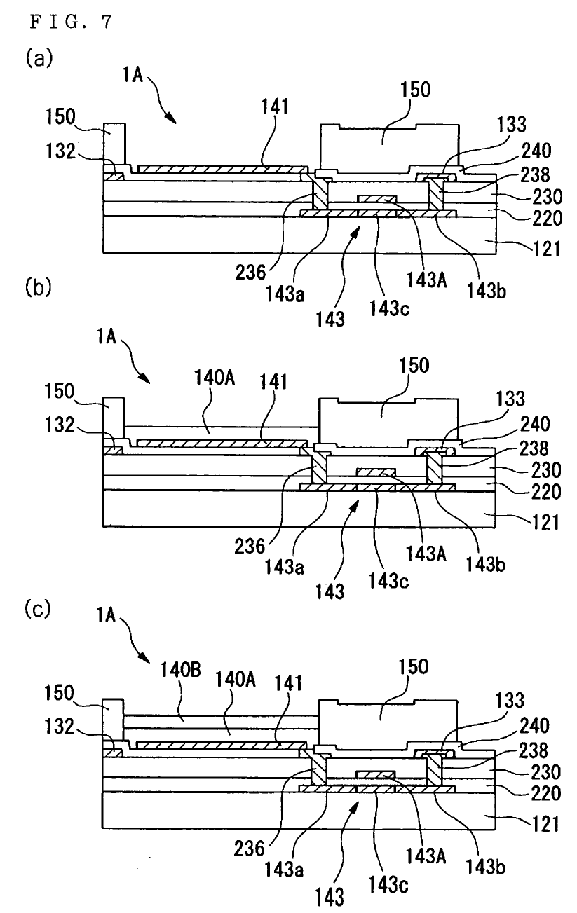

As shown in FIG. 7(a), a partition wall 150 is formed surrounding the pixel electrode 141. This partition wall 150 functions as a divider, and is preferably formed from a material having insulation property, for example, polyimide, silicon oxide, silicon nitride, silicon oxynitride, etc. Regarding the film thickness of the partition wall 150, formation is performed in order that the height becomes, for example, 1 to 2 μm. By forming the partition wall 150 as described above, an adequate height difference is formed between the top surface of the pixel electrode 141 of the pixel 1A and the partition wall 150.

In the present example, the partition wall 150 was formed after the pixel electrode 141 was formed. However, the pixel electrode 141 may be formed after the partition wall 150 is formed.

After the partition wall 150 is formed as described above, a material for forming a positive hole transport layer is arranged in the aforementioned pixel 1A by patterning, and as shown in FIG. 7(b), a positive hole transport layer 140A to become a material portion in the present invention is formed on the pixel electrode 141.

Before formation of this positive hole transport layer 140A, in a manner similar to that in formation of the aforementioned pixel electrode 141, the one in which the material layer 10 is arranged on a second substrate 11, as shown in FIG. 6(a), is prepared in advance. It should be understood that the material for forming the positive hole transport layer to become the material layer 10 is not specifically limited, and those publicly known can be used. Examples thereof can include, for example, pyrazoline derivatives, arylamine derivatives, stilbene derivatives, and triphenyldiamine derivatives. Specific examples include, for example, those described in Japanese Unexamined Patent Application Publication No. 63-70257, Japanese Unexamined Patent Application Publication No. 63-175860, Japanese Unexamined Patent Application Publication No. 2-135359, Japanese Unexamined Patent Application Publication No. 2-135361, Japanese Unexamined Patent Application Publication No. 2-209988, Japanese Unexamined Patent Application Publication No. 3-37992, and Japanese Unexamined Patent Application Publication No. 3-152184. However, the triphenyldiamine derivatives are preferable, and among them, 4,4′-bis(N(3-methylphenyl)-N-phenylamino)biphenyl is considered to be suitable.

A positive hole injection layer may be formed instead of the positive hole transport layer, and furthermore, both of the positive hole injection layer and the positive hole transport layer may be formed. At that time, examples of materials for forming the positive hole injection layer include, for example, copper phthalocyanine (CuPc), polyphenylene vinylene that is polytetrahydrothiophenylphenylene, 1,1-bis-(4-N,N-ditolylaminophenyl)cyclohexane, and tris(8-hydroxyquinolinol) aluminum, and in particular, copper phthalocyanine (CuPc) is used preferably.

As the second substrate 11, in a manner similar to that in formation of the pixel electrode 141, a polyethylene terephthalate film, etc., are used. Regarding formation of the aforementioned material layer 10, various methods can be adopted without specific limitation, and, for example, an evaporation method and a method in which coating is performed on the second substrate 11 by evaporation, spin coating using a solvent, ink jet, dipping, brush coating, etc., are adopted.

Subsequently, the second substrate 11 prepared as described above is arranged with the material layer 10 inside, as shown in FIG. 6(b), on the surface side of the transparent substrate 121.

As shown in FIG. 6(c), a light beam, for example, a laser beam, is emitted from the reverse surface side of the transparent substrate 121 in accordance with a pattern of the desired positive hole transport layer 140A, and this light beam is applied to the surface of the material layer 10 facing the portion to become the aforementioned pixel 1A. According to this, the material in this material layer 10, that is, the material for forming the positive hole transport layer 140A, is allowed to fly and shift onto the portion to become the pixel 1A as described above, this material for formation is allowed to deposit onto the pixel electrode 141 and, therefore, the positive hole transport layer 140A is formed.

Regarding the light beam used for the formation of this positive hole transport layer 140A as well, in a manner similar to that in the case of the aforementioned pixel electrode 141, various stationary source light beams and a laser beam are used.

The film thickness of the positive hole transport layer 140A is also controlled to become an appropriate thickness by adjusting, for example, the application time of the light beam. Furthermore, as described above, the film thickness may be controlled to become an optimum thickness (appropriate thickness) by using a quartz type film thickness monitor, or by monitoring spectroscopic data, for example, emission intensity and light absorption intensity.

A positive hole injection layer may be formed using the aforementioned copper phthalocyanine (CuPc), etc., instead of formation of the positive hole transport layer 140A described above. In particular, preferably, the positive hole injection layer is formed on the pixel electrode 141 side in advance of formation the positive hole transport layer 140A, and furthermore, the positive hole transport layer 140A is formed. By forming the positive hole injection layer together with the positive hole transport layer 140A, an increase of the driving voltage can be controlled and, in addition, the driving life (half-life) can be extended as well.

After the positive hole transport layer 140A is formed as described above, a material for forming a luminescent layer is arranged in the aforementioned pixel 1A by patterning, and as shown in FIG. 7(c), the luminescent layer 140B to become a material portion in the present invention is formed on the positive hole transport layer 140A.

Before formation of this luminescent layer 140B, in a manner similar to that in formation of the aforementioned pixel electrode 141, the one in which the material layer 10 is arranged on the second substrate 11, as shown in FIG. 6(a), is prepared in advance. It should be understood that the material for forming the luminescent layer to become the material layer 10 is not specifically limited, and low-molecular organic luminescent coloring matters and macromolecular luminescent materials, that is, various luminescent substances made of fluorophors or phosphors, can be used. Among conjugate macromolecules to become luminescent substances, those having an arylene vinylene structure are especially preferable. Examples of usable low-molecular luminophors include, for example, naphthalene derivatives, anthracene derivatives, perylene derivatives, coloring matters of polymethine-base, xanthene-base, coumarin-base, cyanine-base, etc., metal complexes of 8-hydroquinoline and derivatives thereof, aromatic amines, tetraphenylcyclopentadiene derivatives, and publicly known materials described in Japanese Unexamined Patent Application Publication No. 57-51781, Japanese Unexamined Patent Application Publication No. 59-194393, and the like.

When the macromolecular luminescent materials are used as the material for forming the luminescent layer, macromolecules having a luminescent group in a side chain can be used, and those having a conjugate structure in the main chain are preferable. In particular, polythiophene, poly-p-phenylene, polyarylene vinylene, polyfluorene, and derivatives thereof are preferable. Among them, polyarylene vinylene and derivatives thereof are preferable. The polyarylene vinylene and derivatives thereof are polymers containing a repeating unit which is represented by the following Chemical formula (1) and which constitutes 50% by mole or more of the total repeating units. More preferably, the repeating unit represented by the following Chemical formula (1) constitutes 70% by mole or more of the total repeating units although depending on the structure of the repeating unit.
—Ar—CR═CR′— (1)
where Ar denotes an arylene group or heterocyclic compound group, each having the number of carbon atoms involving in conjugated bonds of 4 or more, but 20 or less, and R and R′ denote independently a group selected from the group consisting of hydrogen, alkyl groups having the carbon number of 1 to 20, aryl groups having the carbon number of 6 to 20, heterocyclic compounds having the carbon number of 4 to 20, and a cyano group.

The macromolecular luminescent materials may includes aromatic compound groups or derivatives thereof, heterocyclic compounds or derivatives thereof, groups produced by combination thereof, and the like as repeating units other than the repeating unit represented by Chemical formula (1). Furthermore, the repeating units represented by Chemical formula (1) or other repeating units may be joined by a nonconjugated unit having an ether group, ester group, amide group, imide group, etc., and those nonconjugated parts may be contained in the repeating units.

Regarding the aforementioned macromolecular luminescent materials, Ar in Chemical formula (1) is an arylene group or heterocyclic compound group, each having the number of carbon atoms involving in conjugated bonds of 4 or more, but 20 or less, and aromatic compound groups or derivatives thereof, heterocyclic compound groups or derivatives thereof, groups produced by combination thereof, and the like represented by the following Chemical formula (2) are exemplified. 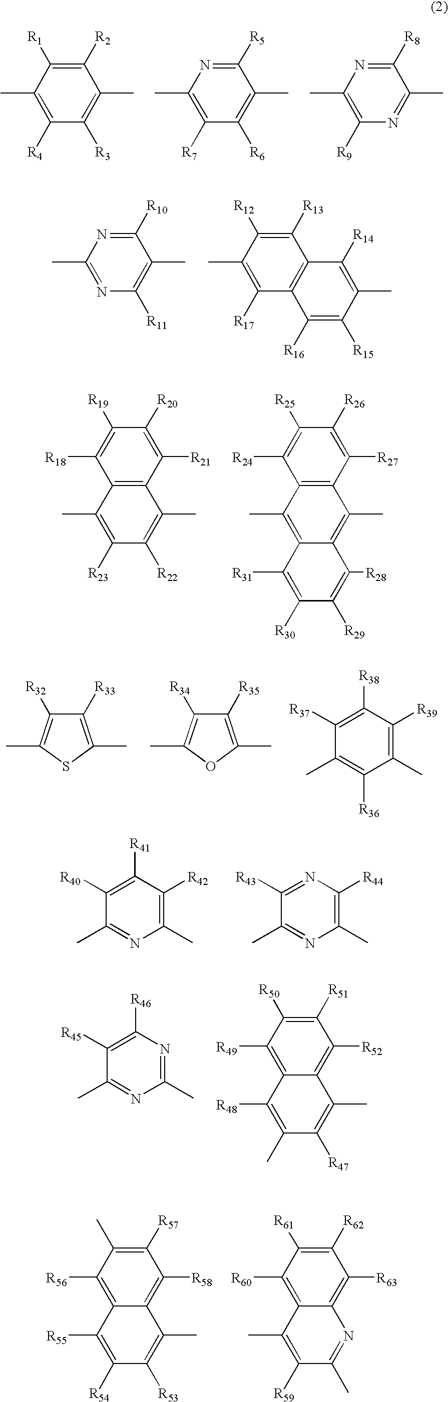 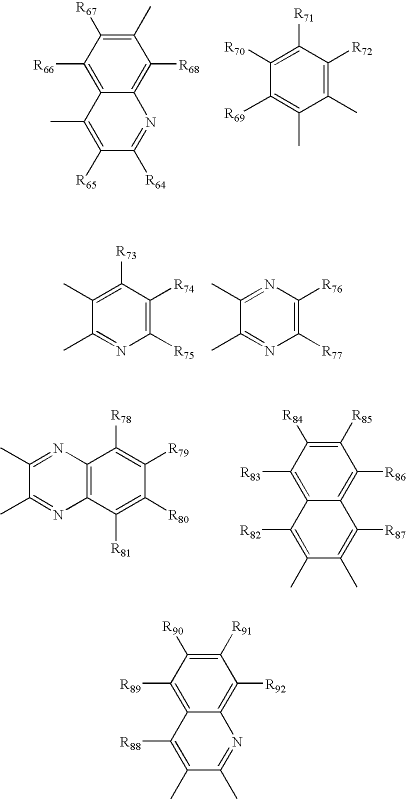
where R₁ to R₉₂ denote independently a group selected from the group consisting of hydrogen, alkyl groups, alkoxy groups, and alkylthio groups, each having the carbon number of 1 to 20; aryl groups and aryloxy groups, each having the carbon number of 6 to 18; and heterocyclic compound groups having the carbon number of 4 to 14.

Among them, a phenylene group, substituted phenylene groups, a biphenylene group, substituted biphenylene groups, a naphthalenediyl group, substituted naphthalenediyl groups, an anthracene-9,10-diyl group, substituted anthracene-9,10-diyl groups, a pyridine-2,5-diyl group, substituted pyridine-2,5-diyl groups, a thienylene group, and substituted thienylene groups are preferable. A phenylene group, biphenylene group, naphthalenediyl group, pyridine-2,5-diyl group, and thienylene group are further preferable.

The case where R and R′ in Chemical formula (1) are hydrogen or a substituent other than a cyano group will be described. Examples of alkyl groups having the carbon number of 1 to 20 include, for example, a methyl group, ethyl group, propyl group, butyl group, pentyl group, hexyl group, heptyl group, octyl group, decyl group, and lauryl group, and the methyl group, ethyl group, pentyl group, hexyl group, heptyl group, and octyl group are preferable. Examples of aryl groups include, for example, a phenyl group, 4-C1 to C12 alkoxyphenyl groups (C1 to C12 denotes that the number of carbon is 1 to 12. Hereafter the same holds true.), 4-C1 to C12 alkylphenyl groups, a 1-naphthyl group, and a 2-naphthyl group.

From the viewpoint of solubility in solvents, preferably, Ar in Chemical formula (1) includes at least one group selected from the group consisting of alkyl groups, alkoxy groups, and alkylthio groups, each having the carbon number of 1 to 20, aryl groups and aryloxy groups, each having the carbon number of 6 to 18, and heterocyclic compound groups having the carbon number of 4 to 14.

As constituents thereof, the following constituents are exemplified. Examples of alkyl groups having the carbon number of 4 to 20 include, for example, a butyl group, pentyl group, hexyl group, heptyl group, octyl group, decyl group, and lauryl group, and the pentyl group, hexyl group, heptyl group, and octyl group are preferable. Examples of alkoxy groups having the carbon number of 4 to 20 include, for example, a butoxy group, pentyloxy group, hexyloxy group, heptyloxy group, octyloxy group, decyloxy group, and lauryloxy group, and the pentyloxy group, hexyloxy group, heptyloxy group, and octyloxy group are preferable. Examples of alkylthio groups having the carbon number of 4 to 20 include, for example, a butylthio group, pentylthio group, hexylthio group, heptylthio group, octylthio group, decyloxy group, and laurylthio group, and the pentylthio group, hexylthio group, heptylthio group, and octylthio group are preferable. Examples of aryl groups include, for example, a phenyl group, 4-C1 to C12 alkoxyphenyl group, 4-C1 to C12 alkylphenyl group, 1-naphthyl group, and 2-naphthyl group. Examples of aryloxy groups include a phenoxy group. Examples of heterocyclic compound groups include, for example, a 2-thienyl group, 2-pyrrolyl group, 2-furyl group, and 2-, 3-, or 4-pyridyl group. Although the number of these substituents varies depending on the molecular weights of the macromolecular luminescent materials and the configurations of the repeating units, from the viewpoint of production of macromolecular luminescent materials having high solubility, regarding these substituents, it is more preferable that at least one constituent is included in every 600 in terms of molecular weight.

The aforementioned macromolecular luminescent material may be a random, block, or graft copolymer, or may be a macromolecule having an intermediate structure between them, for example, a random copolymer taking on properties of block. The random copolymer taking on properties of block, or a block or graft copolymer is preferable compared with a completely random copolymer from the viewpoint of producing a macromolecular luminescent material having a high quantum yield of emission. Since the organic electroluminescent element formed here uses emission from a thin film, the macromolecular luminescent material which brings about emission in solid state is used.

When a solvent is used in formation of the material layer 10 using the macromolecular luminescent material, chloroform, methylene chloride, dichloroethane, tetrahydrofuran, toluene, xylene, etc., are used suitably. In general, 0.1% by weight or more of macromolecular luminescent material can be dissolved in these solvents although depending on the structure and molecular weight of the macromolecular luminescent material used. The aforementioned macromolecular luminescent materials preferably have a molecular weight of 10³ to 10⁷ in terms of polystyrene, and the degrees of polymerization thereof also vary depending on the repeating structure and the proportion thereof. From the viewpoint of a film making property, in general, the total number of repeating structures is preferably 4 to 10,000, more preferably, is 5 to 3,000, and especially preferably, is 10 to 2,000.

It should be understood that a method for synthesizing such a macromolecular luminescent material is not specifically limited, and, for example, Wittig reaction of a dialdehyde compound in which two aldehyde groups are bonded to an arylene group and a diphosphonium salt produced from a compound in which two halogenated methyl groups are bonded to an arylene group and triphenylphosphine is exemplified. As another method for synthesis, a method for dehydrohalogenation of a compound in which two halogenated methyl groups are bonded to an arylene group is exemplified. Furthermore, a sulfonium salt decomposition method in which the macromolecular luminescent material is produced by a heat treatment of an intermediate obtained from polymerization of a sulfonium salt of the compound in which two halogenated methyl groups are bonded to an arylene group using an alkali is exemplified. In any of the methods for synthesis, since a compound having a skeleton of other than an arylene group is added as a monomer, and the structure of the repeating unit contained in the macromolecular luminescent material produced can be changed by changing the abundance ratio thereof, addition may be adjusted in order that the repeating unit represented by Chemical formula (1) becomes 50% by mole or more and, thereafter, copolymerization may be performed. Among these, the method using the Wittig reaction is preferable from the viewpoint of the control of reaction and the yield.

More specifically, a method for synthesizing an arylene vinylene copolymer as an example of the aforementioned macromolecular luminescent material will be described. For example, when the macromolecular luminescent material is produced by the Wittig reaction, for example, a bis(halogenated methyl)compound, more specifically, 2,5-dioctyloxy-p-xylylenedibromide, for example, is reacted with triphenylphosphine in a N,N-dimethylformamide solvent and, therefore, a phosphonium salt is synthesized. This and a dialdehyde compound, more specifically, terephthalaldehyde, for example, are condensed in ethyl alcohol by the Wittig reaction using lithium ethoxide and, therefore, a macromolecular luminescent material containing a phenylene vinylene group and a 2,5-dioctyloxy-p-phenylene vinylene group is produced. At this time, in order to produce a copolymer, two sorts or more of diphosphonium salts and/or two sorts or more of dialdehyde compounds may be reacted.

When these macromolecular luminescent materials are used as the materials for forming a luminescent layer, since the purity thereof affects the emission property, after synthesis is performed, desirably, a purification treatment, for example, refining by reprecipitation and fractionation by chromatograph, is performed.

As the materials for forming the luminescent layer made of the aforementioned macromolecular luminescent material, in order to perform full-color display, materials of three colors, red, green, and blue, for forming the luminescent layer are individually made into films and, therefore, made into material layers 10 on the second substrates 11, and are subjected to use. In other words, in the present example, three sorts of substrates, the second substrate 11 provided with the material for forming a luminescent layer exhibiting red as the material layer 10, the second substrate 11 provided with the material for forming a luminescent layer exhibiting green as the material layer 11, and the second substrate 11 provided with the material for forming a luminescent layer exhibiting blue as the material layer 10, are prepared. Then, patterning is performed using these sequentially as described later and, therefore, the luminescent layer 140B exhibiting red, the luminescent layer 140B exhibiting green, and the luminescent layer 140B exhibiting blue are formed individually.

Regarding the second substrate 11, in a manner similar to that in formation of the pixel electrode 141, a polyethylene terephthalate film, etc., are used. Regarding formation of the aforementioned material layer 10, various methods can be adopted without specific limitation, and, for example, a method in which coating is performed on the second substrate 11 by brush coating, etc., using a solvent is adopted.

Subsequently, the second substrate 11 prepared as described above is arranged with the material layer 10 thereof inside, as shown in FIG. 6(b), on the surface side of the transparent substrate 121. In the transparent substrate 121 here, “transparent” refers to having optical transparency with respect to the light beam used. For example, in the case where near-infrared light on the order of 800 nm, such as a titanium sapphire laser, is used, light may adequately passes through even when not transparent with respect to human eyes. Consequently, those having optical transparency with respect to such a light beam used can be used as the transparent substrates 121 here. However, when the light emitted from the luminescent layer 140B is allowed to pass through this transparent substrate 121 for application, it is a matter of course that this transparent substrate must have a light-transmission property which does not prevent, by a large degree, the aforementioned emitted light from passing through.

As shown in FIG. 6(c), a light beam, for example, a laser beam, is emitted from the reverse surface side of the transparent substrate 121 in accordance with a pattern of the desired luminescent layer 140B, and this light beam is applied to the surface of the material layer 10 facing the portion to become the aforementioned pixel 1A. According to this, the material in this material layer 10, that is, the material for forming the luminescent layer 140B, is allowed to fly and shift onto the portion to become the aforementioned pixel 1A, this material for formation is allowed to deposit onto the pixel electrode 141 and, therefore, the luminescent layer 140B is formed. When these luminescent layers 140B are formed, as described above, three sorts of the second substrates 11 corresponding individually to red, green, and blue are prepared in advance. Then, patterning is performed using them sequentially and, therefore, the luminescent layer 140B exhibiting red, the luminescent layer 140B exhibiting green, and the luminescent layer 140B exhibiting blue are formed individually (in FIG. 7(c), only one luminescent layer is shown).

Regarding the light beam used for the formation of this luminescent layer 140B as well, in a manner similar to that in the case of the aforementioned pixel electrode 141, various stationary source light beams and a laser beam are used.

The film thickness of the luminescent layer 140B is also controlled to become an appropriate thickness by adjusting the application time of the light beam. Furthermore, as described above, the film thickness may be controlled to become an optimum thickness (appropriate thickness) by using a quartz type film thickness monitor, or by monitoring spectroscopic data, for example, emission intensity and light absorption intensity.

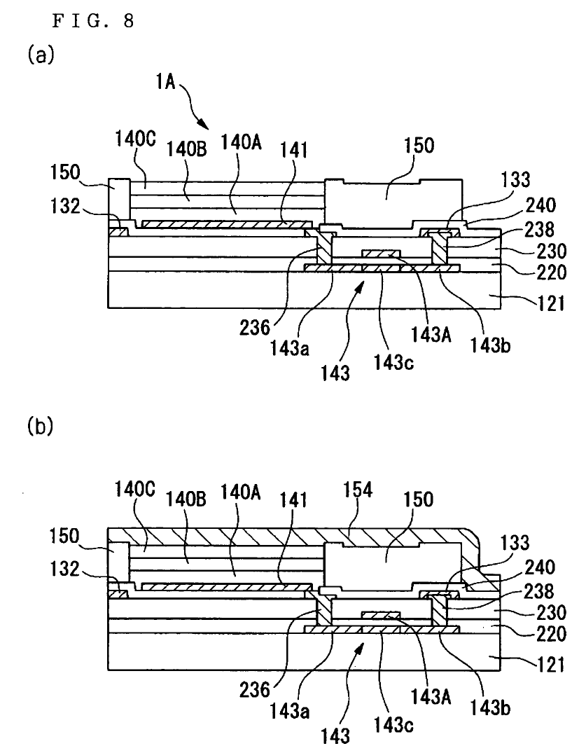

After the luminescent layer 140B is formed as described above, a material for forming an electron transport layer is arranged in the aforementioned pixel 1A by patterning, and as shown in FIG. 8(a), the electron transport layer 140C to become a material portion in the present invention is formed on the luminescent layer 140B.

Before formation of this electron transport layer 140C as well, in a manner similar to that in formation of the aforementioned pixel electrode 141, the one in which the material layer 10 is arranged on the second substrate 11, as shown in FIG. 6(a), is prepared in advance. The material for forming the electron transport layer to become the material layer 10 is not specifically limited, and examples thereof include, for example, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, and metal complexes of 8-hydroxyquinoline and derivatives thereof. Similarly to the materials for forming the aforementioned positive hole transport layer, specific examples include, for example, those described in Japanese Unexamined Patent Application Publication No. 63-70257, Japanese Unexamined Patent Application Publication No. 63-175860, Japanese Unexamined Patent Application Publication No. 2-135359, Japanese Unexamined Patent Application Publication No. 2-135361, Japanese Unexamined Patent Application Publication No. 2-209988, Japanese Unexamined Patent Application Publication No. 3-37992, and Japanese Unexamined Patent Application Publication No. 3-152184. In particular, 2-(4-biphenylyl)-5-(4-t-butylphenyl)-1,3,4-oxadiazole, benzoquinone, anthraquinone, and tris(8-quinolinol)aluminum are considered to be suitable.

The aforementioned materials for forming the positive hole transport layer 140A and the materials for forming the electron transport layer 140C may be mixed into the materials for forming the luminescent layer 140B, and may be used as the materials for forming the luminescent layer. In that case, although the usage of the materials for forming the positive hole transport layer and the materials for forming the electron transport layer vary depending on, for example, the sorts of the compounds used, the usage is determined appropriately within the range of the quantity that does not inhibit adequate film making property and emission property in consideration of them. In general, it is specified to be 1 to 40% by weight relative to the material for forming the luminescent layer, and further preferably, is specified to be 2 to 30% by weight.

After the electron transport layer 140C is formed as described above, as shown in FIG. 8(b), a counter electrode 154 is formed on all over the surface of the transparent electrode 121 or in the shape of stripes and, therefore, an organic electroluminescent element is produced. Regarding formation of this counter electrode 154, in particular, when this is formed on all over the surface of the transparent electrode 121, an evaporation method is used suitably. However, when formed in the shape of stripes, the method for forming the aforementioned pixel electrode 141, that is, the method for patterning of the present invention shown in FIGS. 6(a) to (c), is used preferably. The reason is that according to the method for patterning (film making method) of the present invention, a wiring pattern can also be formed with ease by using a metal or an organic or inorganic conductive material. It should be understood that the method for patterning (film making method) of the present invention is not limited to the case where the counter electrode 154 is formed in the shape of stripes, and as a matter of course, can be adopted in the case where the counter electrode is formed on all over the surface of the transparent electrode 121.

As a matter of course, such a counter electrode 154 may be formed from one layer made of a single metal material, for example, Al, Mg, Li, and Ca, or an alloy material of Mg:Ag (10:1 alloy). However, the counter electrode 154 may be formed as a metal (including alloy) layer made of two layers or three layers. Specifically, those having laminated structures, for example, Li₂O (on the order of 0.5 nm)/Al, LiF (on the order of 0.5 nm)/Al, and MgF₂/Al, can also be used.

In the case where the counter electrode 154 is formed from two layers of metal layers composed of a laminate of a first metal layer and a second metal layer in that order from the luminescent layer 140B side, preferably, the first metal layer on the luminescent layer 140B side is made of a metal having a work function exceeding 3.7 eV, and the thickness is 20 nm or less. The second metal layer in contact with the first metal layer is preferably made of a metal (including alloy) having a work function of 3.7 eV or less. In the case where the counter electrode 154 is formed from three layers of metal layers, preferably, the first metal layer and the second metal layer are similar to those in the case of the aforementioned two-layer configuration, and a third metal layer is made of a metal selected from the group consisting of platinum, silver, gold, nickel, titanium, tantalum, indium, and aluminum.

It should be understood that the metal used for the first metal layer is not specifically limited as long as the work function thereof exceeds 3.7 eV, and a metal selected from the group consisting of platinum, silver, gold, nickel, titanium, tantalum, indium, aluminum, scandium, lead, and zinc is preferable, and platinum, silver, gold, indium, or aluminum is more preferable. The thickness of the first metal layer is essentially 20 nm or less, and preferably, is 20 nm or less, but 1 nm or more, and further preferably, is 10 nm or less, but 2 nm or more. As the method for forming the first metal layer, the method for patterning of the present invention, an evaporation method, a sputtering method, etc., can be adopted.

The metal used for the second metal layer of the counter electrode 154 is essentially a metal (including alloy) having the work function of 3.7 eV or less. Specific examples thereof include lithium, strontium, calcium, magnesium, and alloys containing them. Lithium, strontium, calcium or an alloy containing them is preferable, and lithium or an alloy containing this is especially preferable. In the case where an alloy is used for the second metal layer, there is no specific limitation as long as a metal having the work function of 3.7 eV or less is contained, and examples of alloys include alloys of a metal having the work function of 3.7 eV or less and silver, gold, platinum, aluminum, indium, etc. Specific examples thereof include, for example, lithium-aluminum alloys, lithium-silver alloys, lithium-indium alloys, potassium-aluminum alloys, potassium-silver alloys, and potassium-indium alloys. Regarding the compositional ratio of the alloy (the compositional ratio of the metal having the work function of 3.7 eV or more and the metal having the work function of 3.7 eV or less), an alloy having a compositional ratio of the metal having the work function of 3.7 eV or less in the total counter electrode 154, that is, the first, second, and third metal layers, of 0.005% or more, but 99.9% or less is chosen. The compositional ratio is preferably 0.005% or more, but 10% or less, and more preferably, is 1% or more, but 2% or less. The thickness thereof is preferably 10 nm or more, but 1,000 nm or less, and more preferably, is 20 nm or more, but 200 nm or less. As the method for forming the second metal layer as well, the method for patterning of the present invention, an evaporation method, a sputtering method, and the like, can be adopted.

The third metal layer of the counter electrode 154 is made of a noble metal resistant to oxidation and corrosion in the air, a transition metal which brings about passivation, a metal having a small Young's modulus, or an alloy. Specifically, the third metal layer is made of a thin film of metal selected from the group consisting of platinum, silver, gold, indium, and aluminum, and indium or aluminum is further preferable. As the method for forming the third metal layer of the counter electrode 154 as well, the method for patterning of the present invention, an evaporation method, a sputtering method, etc., can be adopted. Although the thickness of this third metal layer is not specifically limited, in the case where the third metal layer is formed by the evaporation method, sputtering method, and the like, when the thickness is reduced excessively, shielding of the first metal layer or the second metal layer from the outside air becomes inadequate. Consequently, 50 nm or more is preferable, and 100 nm or more is further preferable.

In the present example, in addition to the aforementioned positive hole injection layer (not shown in the drawing), positive hole transport layer 140A, luminescent layer 140B, and electron transport layer 140C, a whole blocking layer may be formed, for example, on the counter electrode 154 side of the luminescent layer 140B in order to achieve extension of the life of the luminescent layer 140B. As the material for forming such a whole blocking layer, for example, BAlq is used.

In the present example, the pixel electrode 141, positive hole transport layer 140A, luminescent layer 140B, and electron transport layer 140C were formed by the method for patterning of the present invention and, furthermore, the method for patterning of the present invention was able to adopt with respect to the counter electrode 154. However, in particular, when the positive hole transport layer 140A and later layers are formed by the present method, the wavelength and the intensity, etc., of the light beam, for example, the laser beam, must be taken in consideration. That is, for example, in the case where the luminescent layer 140B is formed, the light beam must pass through the positive hole transport layer 140A. However, when the material for forming the positive hole transport layer 140A exhibits remarkable light absorption, required quantity of light beam does not reach the material layer 10 made of the material for forming the luminescent layer 140B and, therefore, the luminescent layer 140B may not be formed. In such a case, a desired layer can be formed by changing the incident direction or the focal distance of the light beam, and when the laser beam is used, by using the beam having the pulse width of a nanosecond or less, preferably picosecond order, and further preferably femtosecond order so as to bring about multiphoton excitation, and the like.

As described above, the second thin film transistor 143 is formed in order that this is not located directly below the portion to become the pixel 1A, and thereby, the second thin film transistor 143 is allowed to avoid the influence of the light beam during patterning. However, in order to prevent application of the light beam to the second thin film transistor 143 and the first thin film transistor 142 with reliability, a lightproof film of a metal, etc., is preferably formed on the transparent substrate 121 side of these transistors. Likewise, in the case where the incident direction of the light beam is changed in order to avoid light absorption of the previously formed layer and, therefore, light beam is applied to the transistor, desirably, the lightproof film is formed.

In order to avoid the adverse effect on the transistors and the light absorption of the previously formed layer described above, the light beam is not applied from the transparent substrate 121 side to the material layer 10 on the second substrate 11, but the light beam may be applied from the side opposite to the transparent substrate 121, that is, the reverse surface side of the second substrate 11 to the surface portion of the material layer 10 on the surface side thereof and, thereby, the material may be allowed to fly and shift onto the transparent substrate 121 side. However, in that case, the second substrate 11 must also be formed from a transparent or translucent material.

In the present example, the pixel electrode 141, positive hole transport layer 140A, luminescent layer 140B, and electron transport layer 140C were formed by the method for patterning of the present invention and, furthermore, the method for patterning of the present invention was able to adopt with respect to the counter electrode 154. However, not all of them may be formed by the method for patterning of the present invention, but at least one may be formed.

When the material layer 10 can be formed not on the second substrate 11 but discretely, for example, when a metal foil can be used directly as an electrode material, the material layer 10 made of this metal foil may be arranged directly on the transparent substrate 121 without use of the second substrate 11 and, thereafter, patterning may be performed.

Regarding such a method for patterning of the present invention, since the material in the material layer can be shifted onto the transparent substrate 121 by being irradiated with the light beam. Consequently, when application of the light beam is performed in accordance with a desired pattern, the material portion with a desired pattern can be formed on the transparent substrate 121 with ease and with precision. The material in the material layer is not always specifically unlimited, and the flexibility in selection of the material can be increased. Therefore, as a matter of course, it is possible to apply to various sorts of patterning and, in addition, even in patterning of one constituent, since there is no limitation with respect to the material used, the material can be selected arbitrarily from various materials and patterning can be performed.

Since the light beam is applied to the material layer from the transparent substrate 121 side through the transparent substrate 121, by the transparent substrate 121 being located on the surface side, to which the light beam is applied, of the material layer, the material flied from the material layer becomes likely to shift onto the transparent substrate 121 side and therefore, the material portion can be patterned excellently onto the transparent substrate 121.

When, especially, the laser beam is used as the light beam to be applied, a stable and high-energy light beam can be applied and, therefore, excellent patterning can be performed.

By making the material layer a transparent electrode material, for example, ITO, or an electrode material made of a general metal, when, for example, the pixel electrode 141 of the organic electroluminescent element is made from ITO as described above, etching with a strong acid is not performed in contrast to the conventional patterning and, therefore, other metal wirings on the element are not adversely affected by corrosion, etc.

Since the positive hole transport layer 140A, the luminescent layer 140B, and the electron transport layer 140C constituting the organic electroluminescent element are formed individually, these positive hole transport layer 140A, luminescent layer 140B, and electron transport layer 140C can be formed with ease and with precision and, in addition, the materials for formation thereof can be selected with a high degree of flexibility.

Regarding the method for manufacturing an organic electroluminescent element using such a method for patterning, since the positive hole transport layer 140A, the luminescent layer 140B, and the electron transport layer 140C can be formed with ease and with precision and, in addition, the materials for formation thereof can be selected with a high degree of flexibility, improvement of the quality of the resulting organic electroluminescent element and reduction of the cost can be achieved.

Next, a second example of the case where the method for patterning of the present invention is applied as a method for manufacturing an organic electroluminescent element will be described.

The present example is different from the previous first example in that regarding formation of, especially, the luminescent layer 140B, a second substrate provided with a material layer arranged beforehand with a desired pattern is used.

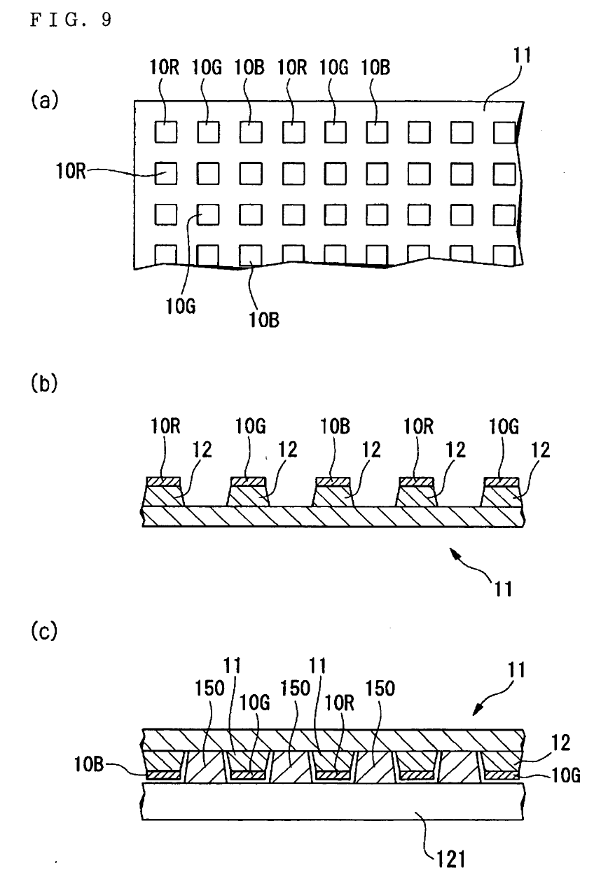

In other words, in the present example, as shown in FIG. 9(a), the material layers 10R (corresponding to red), 10G (corresponding to green), and 10B (corresponding to blue) made of materials for forming luminescent layers corresponding to red, green, and blue are formed on the second substrate 11, and subsequently, in a manner similar to that in the previous example, each of the luminescent layers 140B of red, green, and blue are formed by patterning using this second substrate 11.

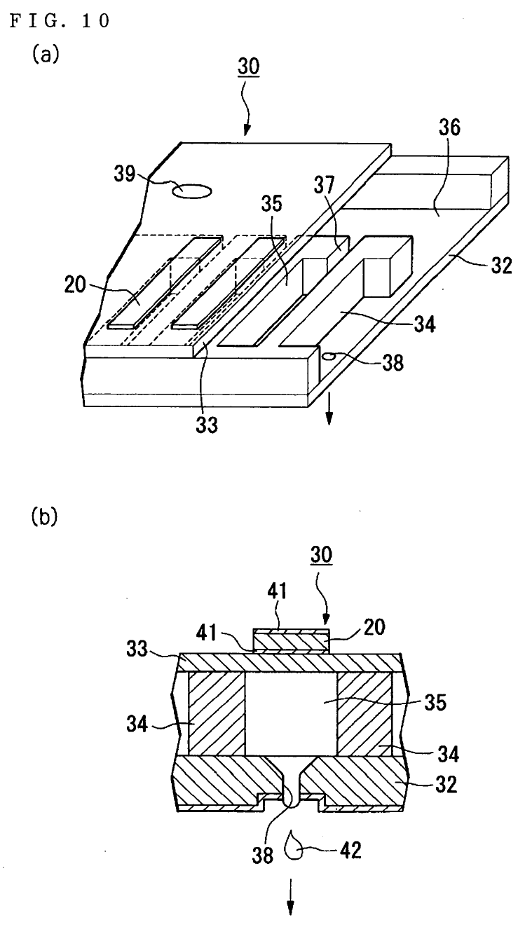

Regarding each of the material layers 10R, 10Q and 10B arranged on such a second substrate 11, conventionally known method can be adopted with no specific limitation. However, in particular, an ink-jet method using an ink-jet head 30 shown in FIG. 10(a) is adopted suitably.

As shown in FIG. 10(a), the ink-jet head 30 is provided with, for example, a nozzle plate 32 made of stainless steel and a vibration plate 33, the two being joined with a partition member (reservoir plate) 34 therebetween. A plurality of spaces 35 and a liquid reservoir 36 are arranged by the partition member 34 between the nozzle plate 32 and the vibration plate 33. The inside of each of the spaces 35 and the liquid reservoir 36 is filled with ink, and each of the spaces 35 and the liquid reservoir 36 are communicated through supply ports 37. The nozzle plate 32 is provided with a plurality of nozzle holes 38 for ejecting ink from the spaces 35 in the condition of being aligned in a line. On the other hand, the vibration plate 33 is provided with a hole 39 for supplying ink to the liquid reservoir 36.

As shown in FIG. 10(b), piezoelectric elements (piezo elements) 40 are joined on the surface on the side opposite to the surface facing the space 35 of the vibration plate 33. This piezoelectric element 40 is located between a pair of electrodes 41, and this is configured to flex while protruding outside when being energized. Under such a configuration, the vibration plate 33 joining with the piezoelectric element 40 flexes outside simultaneously while being integrated with the piezoelectric element 40 and, thereby, the volume of the space 35 is increased. Consequently, the ink corresponding to the increment of the volume flows into the space 35 from the liquid reservoir 36 through the supply port 37. When energization of the piezoelectric element 40 is canceled under this condition, both of the piezoelectric element 40 and the vibration plate 33 back to the original shape. Therefore, since the space 35 also backs to the original volume, the pressure of the ink in the space 35 is increased, and a droplet 42 of the ink is discharged from the nozzle 38 toward the substrate.

The ink-jet system of the ink-jet head 30 may be a system other than the piezo jet type using the aforementioned piezoelectric element 40, and, for example, the one using an electrothermal converter as an energy generation element may be adopted.

By using the ink-jet head 30 having such a configuration, individual materials for forming the aforementioned luminescent layers are formed while being regularly arranged at predetermined respective positions, that is, the positions corresponding to the positions of individual luminescent layers of the organic electroluminescent element to be formed. Then, the thus produced second substrate 11 is arranged on the transparent substrate 121 in a manner similar to that in the previous example and, in addition, each of the material layers 10R, 10G, and 10B is arranged in accordance with each pixel 1A on the transparent substrate 121.

Subsequently, in a manner similar to that in the previous example, each of the material layers 10R, 10G, and 10B is irradiated with a light beam and, therefore, the luminescent layers 140B of respective colors of red, green, and blue are formed on the positive hole transport layer 140A with a desired pattern, that is, with a desired arrangement.

Regarding the method for patterning as described above, since the materials for formation corresponding to each of the luminescent layers of red, green, and blue are arranged beforehand on the second substrate 11 as the material layers 10R, 10Q, and 10B, respectively, by using this second substrate 11, all of the materials of three colors can be patterned in one step without exchange of the second substrate 11 and, therefore, an increase in efficiency of the patterning step can be achieved.

When the material layers 10R, 10Q and 10B made of the materials for forming the luminescent layer 140B are formed on the second substrate 11, preferably, as shown in FIG. 9(b), convex portions 12 having an appropriate height are formed beforehand at the positions at which these material layers 10R, 10Q, and 10B are to be formed and, thereafter, the material layers 10R, 10G, and 10B are formed thereon. Preferably, the height of the convex portion 12 is specified to be nearly equivalent to the height (preferably, the height slightly lower than that) get by subtracting the height of the material layers 10R, 10G, and 10B to be formed from the depth in the pixel 1A which is made to be concave portion surrounded by the partition wall 150 on the transparent substrate 121, that is, the height corresponding to the depth from the top portion of the partition wall 150 to the positive hole transport layer 140A surface. The shape of the convex portion 12 is preferably specified to be the shape which fits in the aforementioned concave portion surrounded by the partition wall 150 in the condition that the material layers 10R, 10C and 10B are assumed to be arranged thereon.

When the height and the shape are specified to be as described above, as shown in FIG. 9(c), by fitting the convex portion 12 of the second substrate 11 in the concave portion (the portion to become pixel 1A) surrounded by the partition wall 150 of the transparent substrate 121, the arrangement of this second substrate 11 on the transparent substrate 121 and positioning thereof, that is, positioning to bring each of the material layers 10R, 10Q and 10B into correspondence with the portion to become the pixel 1A, become easy. Consequently, an increase in efficiency of the steps and an improvement of positional precision of the resulting luminescent layer 104B can be achieved.

When the convex portions 12 are formed on the second substrate 11, regarding the convex portions 12, an organic material, for example, polyimide, is discharged and applied by coating in a predetermined arrangement using the aforementioned ink-jet method and, thereafter, this is solidified so as to produce the convex portions 12. When the convex portions 12 have been formed, preferably, the top portions of the convex portions 12 are subjected to a treatment to impart affinity for ink (a treatment to impart a lyophilic property with respect to a liquid material discharged from the ink-jet head), and the portion other than those are subjected to a treatment to impart ink repellency (a treatment to impart liquid repellency with respect to a liquid material discharged from the ink-jet head) and, therefore, the material for forming the luminescent layer is selectively applied by coating on the convex portions 12 so as to selectively form the material layers 10R, 10Q, and 10B at desired positions.

Among these treatment to impart affinity for ink and treatment to impart ink repellency, as the treatment to impart ink repellency, for example, a method for surface-treating the surface of the convex portion 12 with fluorine-based compound, etc., is adopted. Examples of fluorine compounds include, for example, CF₄, SF₅, and CHF₃, and examples of surface treatments include a plasma treatment. As the treatment to impart affinity for ink, such a method in which a UV irradiation treatment is further applied to the portion having been previously subjected to the treatment to impart ink repellency and, therefore, polymerization of the polymerized film made of the aforementioned fluorine compound is cleaved so as to have affinity for ink is adopted.

In order to subject the surface (top portion) of the convex portion 12 to the treatment to impart affinity for ink and to subject the portion other than that to the treatment to impart ink repellency by the aforementioned treatment method, initially, the second substrate 11 provided beforehand with the convex portions 12 is coated with the fluorine- based compound, this is polymerized by a plasma polymerization treatment, etc., and therefore, a fluorine-based polymerized film is formed on the second substrate 11 surface. Subsequently, only the surfaces (top portions) of the convex portions 12 are selectively irradiated with ultraviolet rays using a mask for light irradiation prepared beforehand and, therefore, the surfaces (top portions) of the convex portions 12 irradiated are allowed to have affinity for ink.

After only the surfaces (top portions) of the convex portions 12 are thus allowed to have affinity for ink, as described above, each of the materials for forming the luminescent layers is discharged and applied by coating on these convex portions 12 in a predetermined arrangement using the ink-jet method and, thereafter, this is solidified so as to produce the material layers 10R, 10G, and 10B. At this time, since the surface (top portion) of the convex portion 12 has affinity for ink, the ink (luminescent layer material) hit here adheres uniformly on the convex portion 12 surface and, in addition, does not fall on the portion having ink repellency, that is, side surfaces of the convex portions 12. Consequently, the luminescent layer materials are selectively adhered on only the surfaces (top portions) of the convex portions 12 and are solidified. Therefore, as described above, the material layers 10R, 10G, and 10B are selectively formed on only the surfaces (top portions) of the convex portions 12.

When the second substrate 11 thus formed is used, this second substrate 11 is turned upside down, and is fitted to the transparent substrate 121 in the condition that the material layers 10R, 10G, and 10B thereof face downward, as shown in FIG. 9(c).

Next, a third example of the case where the method for patterning of the present invention is applied as a method for manufacturing an organic electroluminescent element will be described.

The present example is different from the previous first and second examples in that when the patterning is performed by applying a light beam, a mask for light irradiation is used in order to selectively perform application of the light beam.

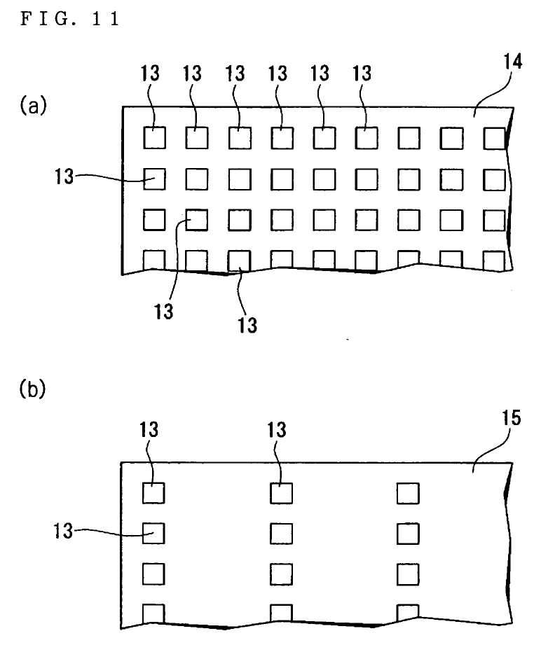

That is, in the present example, when the positive hole transport layer 140A, the luminescent layer 140B, and the electron transport layer 140C, for example, are formed, as shown in FIG. 11(a), a mask 14 is prepared beforehand, in which opening portions (or transparent portions) 13 are formed and arranged at respective positions in accordance with all of (or a part of, for example, a half) the pixels 1A, and the other portion is made to be a lightproof portion.

After the second substrate 10 is arranged on the transparent substrate 121 in a manner similar to that in the first example, the aforementioned mask 14 is set in the condition of being positioned at the reverse side (light irradiation side) of the transparent substrate 121. In other words, set in order that the opening portions 13 are positioned in accordance with respective pixels 1A, and the light beam is applied under that condition. At this time, especially, when the positive hole transport layer 140A and the electron transport layer 140C are patterned, since these are commonly formed at all of the pixels 1A, patterning can be performed without specifically selective application of the light beam. Consequently, when a light source capable of performing surface emission is used, since patterning (formation of the positive hole transport layer 140A or the electron transport layer 140C) in a plurality of pixels 1A can be performed simultaneously, an increase in efficiency of the patterning step can be further accelerated.

When the luminescent layer 140B is patterned, the light beam may be applied selectively using the mask 14 shown in FIG. 11(a) on a opening 13 corresponding to each of the pixels 1A of red, green, and blue basis and, therefore, luminescent layers 140B of respective colors may be formed. However, when pixels 1A of each of red, green, and blue are different only in absolute positions, but have the same arrangement pattern, as shown in FIG. 11(b), a mask 15 is prepared, in which the opening portions (or transparent portions) 13 are formed and arranged at the positions in accordance with the arrangement pattern of the luminescent layer of one color, and the other portion is made to be a lightproof portion.

Subsequently, in a manner similar to that in the first example, after the second substrate 10 provided with, for example, a red material layer, is arranged on the transparent substrate 121, the aforementioned mask 14 is set in the condition of being positioned at the reverse side (light beam irradiation side) of the transparent substrate 121, that is, set in order that the opening portions 13 are positioned in accordance with red pixels 1A, and the light beam is applied under that condition. At this time, since all of the pixels 1A corresponding to the opening portions 13 are made to be red pixels 1A, patterning (formation of the luminescent layer) can be performed without specifically selective application of the light-beam.

After the red luminescent layer is formed as described above, the second substrate 12 is changed to the one provided with, for example, the green material layer, and the aforementioned mask 14 is moved and reset in order that the opening portions 13 thereof are positioned in accordance with the green pixels 1A. The light beam is applied under this condition in a manner similar to that in the case of red and, therefore, the green luminescent layer is formed.

Subsequently, the second substrate 12 is changed to the one provided with the blue material layer, and the aforementioned mask 14 is further moved and reset in order that the opening portions 13 thereof are positioned in accordance with the blue pixels 1A. The light beam is applied under this condition in a manner similar to that in the case of red and, therefore, the blue luminescent layer is formed.

In the method using such a mask 15, in contrast to patterning by an evaporation method, since the mask 15 is only irradiated with the light beam, one mask can be used for patterning with a plurality of materials. Consequently, there is a cost advantage and, in addition, since the luminescent layers 140B of different colors can be patterned only by moving the mask, an increase in efficiency of the patterning step can be achieved.

In patterning of the luminescent layer 140B by using such a mask 15, as a mechanism for moving the mask 15, a control device having a function of adjusting the movement quantity by driving with a pulse control motor disclosed in, for example, Japanese Patent No. 3019095 is used suitably.

Regarding the mask for light irradiation used for patterning, a specific mask may be prepared on a material basis, and patterning may be performed using the mask in contrast to the aforementioned mask 14 which is used for patterning of all of the positive hole transport layer 140A, the luminescent layer 140B, and the electron transport layer 140C, or the mask 15 which is used for patterning of all colors of the luminescent layer 140B.

At that case, for example, when the size or shape are desired to change on a pattern made of each material basis, patterning can be performed in accordance with individual patterns of desired size or shape.

Next, a fourth example of the case where the method for patterning of the present invention is applied as a method for manufacturing an organic electroluminescent element will be described.

The present example is different from the previous first, second, and third examples in that when the luminescent layer 140B is formed, the material thereof is formed from a host/guest-based luminescent material, that is, a luminescent material in which a guest material is added and dispersed in a host material.

Regarding such a luminescent material, as the host material, for example, a macromolecular organic compound and a low molecular material are used suitably, and as the guest material, the one containing a fluorophor or a phosphor for changing the luminescent properties of the resulting luminescent layer is used suitably.

As the macromolecular organic compound, when the material has a low solubility, for example, there are those which can generate a luminescent layer to become a conjugated macromolecular organic electroluminescent element layer by thermosetting as shown by the following Chemical formula (3) after a precursor is applied by coating. For example, regarding some precursor sulfonium salts, sulfonium groups are eliminated by a heat treatment and, therefore, conjugated macromolecular organic compounds are produced.

When the material has a high solubility, some materials are applied by coating without being treated and, thereafter, luminescent layers can be produced by removing the solvents.

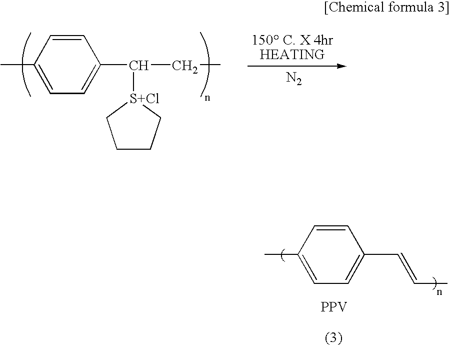

The aforementioned macromolecular organic compound is a solid, exhibits strong fluorescence, and can form a uniform solid ultra-thin film. Furthermore, it has high formability, has high adhesion to the ITO electrode, and can form a strong conjugated macromolecular film after being solidified.

As such a macromolecular organic compound, for example, polyarylene vinylene is preferable. Polyarylene vinylene is soluble in an aqueous solvent or an organic solvent, and when the second substrate 11 is coated, a coating solution is prepared therefrom with ease. Furthermore, since polymerization can be performed under constant conditions, optically high-quality thin film can be obtained as well.

Examples of such polyarylene vinylene include, for example, PPV derivatives, e.g., PPV (poly(para-phenylene vinylene)), MO-PPV (poly(2,5-dimethoxy-1,4-phenylene vinylene)), CN-PPV (poly(2,5-bishexyloxy-1,4-phenylene-(1-cyanovinylene))), MEH-PPV (poly[2-methoxy-5-(2′-ethylhexyloxy)]-para-phenylene vinylene); poly(alkylthiophene), e.g., PTV (poly(2,5-thienylene vinylene)); PFV (poly(2,5-furylene vinylene)), poly(paraphenylene), and polyalkylfluorene. Among them, those made of precursors of PPV or PPV derivatives represented by Chemical formula (4) and polyalkylfluorene represented by Chemical formula (5) (specifically, polyalkylfluorene-based copolymer represented by Chemical formula (6)) are especially preferable.

Since PPV etc., have strong fluorescence, and are also conductive macromolecules in which π electrons forming double bonds are delocalized on polymer chains, high performance organic electroluminescent elements can be produced.

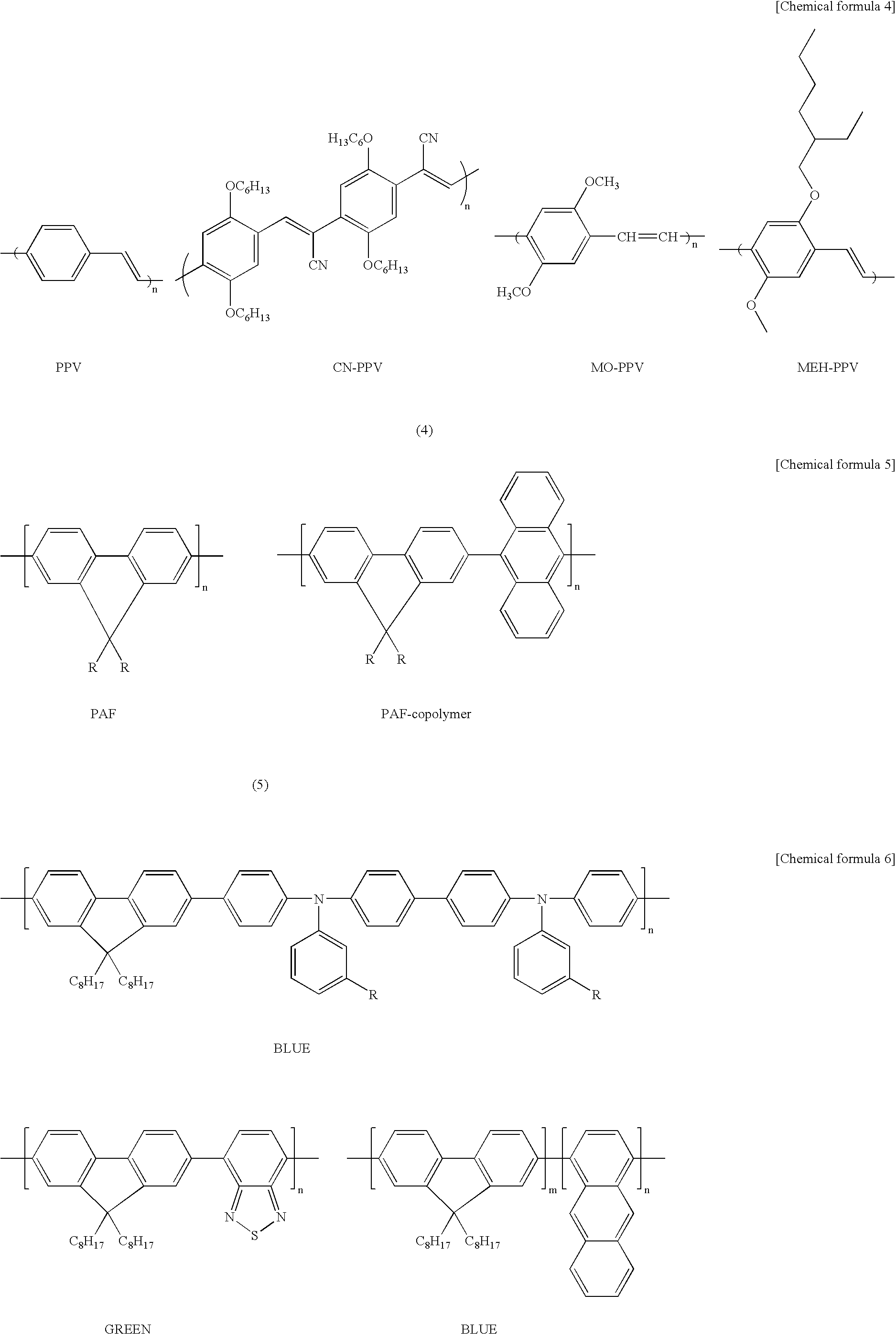

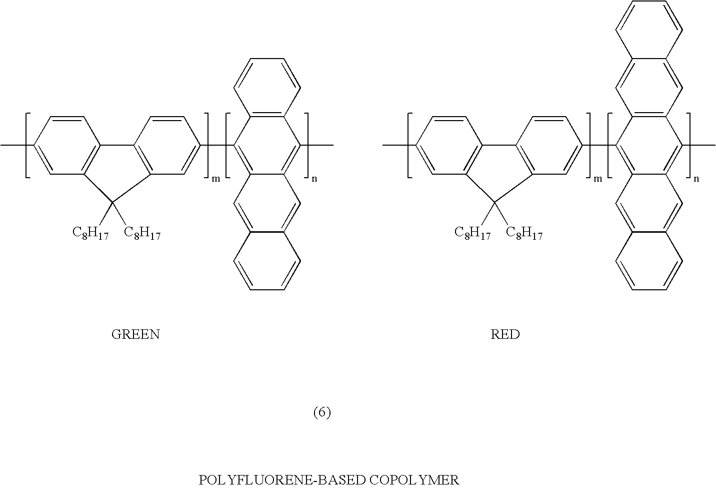

Examples of macromolecular organic compounds and low molecular materials capable of forming luminescent layers other than the aforementioned PPV thin film, that is, those which can be used as host materials in the present example, include, for example, aluminum quinolinol complex (Alq3) and distyrylbiphenyl, BeBq₂ and Zn(OXZ)₂ represented by Chemical formula (7), and those conventionally commonly used, e.g., TPD, ALO, and DPVBi, and, in addition to them, pyrazoline dimer, quinolidinecarboxylic acid, benzopyrylium perchlorate, benzopyranoquinolidine, rubrene, and phenanthroline europium complex, and compositions for organic electroluminescent element containing at least one of them can be used.

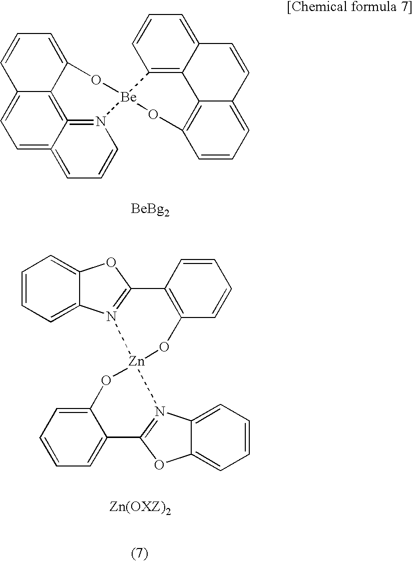

On the other hand, as the guest material added to such host materials, as described above, luminescent coloring matters, for example, fluorophors and phosphors, can be mentioned. In particular, the luminescent coloring matter can change luminescent properties of the luminescent layer and, therefore, is also effective as, for example, a means for improving the luminous efficacy of the luminescent layer or changing the luminescent wavelength (luminescent color). That is, the luminescent coloring matter can be used as not only the luminescent layer material, but also the coloring matter material which performs a luminescent function itself. For example, energy of the exciton generated by carrier recombination on the conjugated macromolecular organic compound molecule can be transferred onto the luminescent coloring matter molecule. In this case, since emission is brought about from only the luminescent coloring matter molecule having a high luminescent quantum efficiency, the current quantum efficiency of the luminescent layer is also increased. Consequently, when the luminescent coloring matter is contained in the material for forming the luminescent layer, the emission spectrum of the luminescent layer is concurrently converted to that of the fluorescent molecule and, therefore, effectiveness is exhibited as a means for changing the luminescent color as well.

Here, the current quantum efficiency refers to a measure for considering the luminescent performance based on the luminescent function, and is defined by the following formula.
ηE=energy of photon discharged/input electric energy

According to conversion of the light absorption maximum wavelength based on doping of the luminescent coloring matter, the primary colors of, for example, red, blue, and green, can be emitted, and as a result, it becomes possible to produce a full-color display material.

Furthermore, by doping the luminescent coloring matter, the luminous efficacy of the electroluminescent element can be improved by a large degree.

When the luminescent layer which emits red light is formed, as the luminescent coloring matter, a laser coloring matter DCM-1, rhodamine or a rhodamine derivative, penylene, or the like is used preferably. The luminescent layer can be formed by doping the host material, for example, PPV, with these luminescent coloring matters. However, in the case where these luminescent coloring matters are soluble in water, when a sulfonium salt which is a PPV precursor having water solubility is doped and, thereafter, a heat treatment is performed, further uniform luminescent layer can be formed. Specific examples of such luminescent coloring matters include, for example, rhodamine B, rhodamine B base, rhodamine 6Q, and rhodamine 101 perchlorate, and at least two of them may be mixed.

When the luminescent layer which emits green light is formed, quinacridone, rubrene, DCJT and derivatives thereof are used preferably. The luminescent layer can also be formed by doping the host material, for example, PPV, with these luminescent coloring matters in a manner similar to that in the aforementioned luminescent coloring matter. However, in the case where these luminescent coloring matters are soluble in water, when a sulfonium salt which is a PPV precursor having water solubility is doped and, thereafter, a heat treatment is performed, further uniform luminescent layer can be formed.

Furthermore, when the luminescent layer which emits blue light is formed, distyrylbiphenyl and derivatives thereof are used preferably. The luminescent layer can also be formed by doping the host material, for example, PPV, with these luminescent coloring matters in a manner similar to that in the aforementioned luminescent coloring matter. However, in the case where these luminescent coloring matters are soluble in water, when a sulfonium salt which is a PPV precursor having water solubility is doped and, thereafter, a heat treatment is performed, further uniform luminescent layer can be formed.

As other luminescent coloring matter having blue emission light, coumarin and derivatives thereof can be mentioned. Among them, although, especially, coumarin itself is insoluble in a solvent, when a substituent is chosen appropriately, the solubility is increased, and some become soluble in a solvent. Specific examples of such luminescent coloring matters include, for example, coumarin-1, coumarin-6, coumarin-7, coumarin-120, coumarin-138, coumarin-152, coumarin-153, coumarin-311, coumarin-314, coumarin-334, coumarin-337, and coumarin-343.

As another luminescent coloring matter having blue emission light, tetraphenylbutadiene (TPB) or a TPB derivative, DPVBi, or the like can be mentioned. These luminescent coloring matters are soluble in an aqueous solution similarly to the aforementioned red-emitting coloring matters, etc., and are compatible with PPV so as to form the luminescent layer with ease.

The luminescent coloring matters described above may be used alone, or a mixture of at least two thereof may be used on a color basis.

As such luminescent coloring matters, those represented by Chemical formula (8), those represented by Chemical formula (9), and those represented by Chemical formula (10) are used.

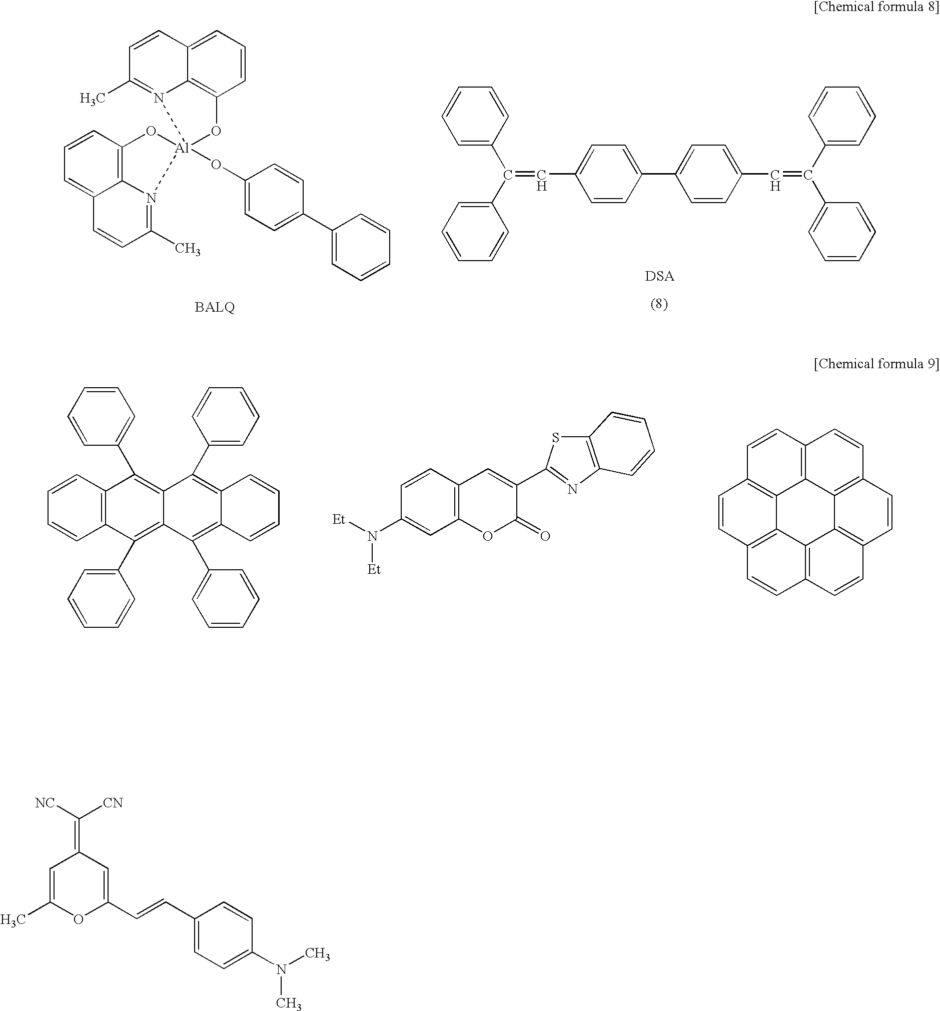

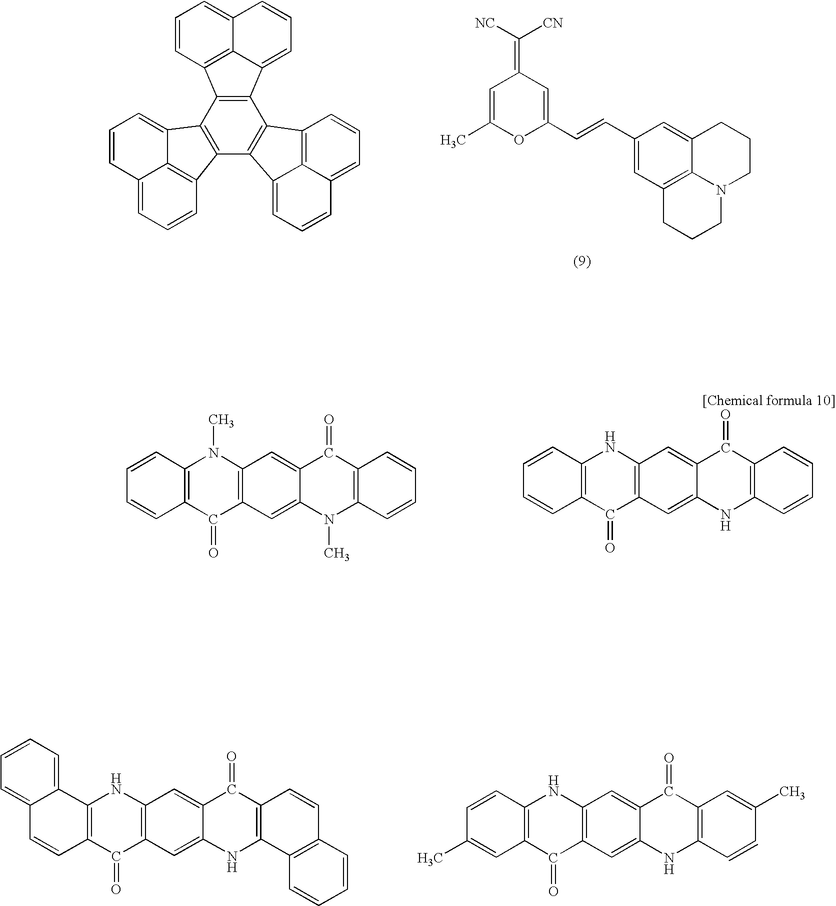

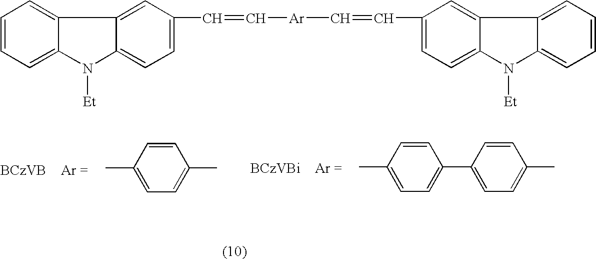

These luminescent coloring matters are added to the host material composed of the aforementioned conjugated macromolecular organic compounds, etc., by a method described later at preferably 0.5% to 10% by weight, and more preferably, 1.0% to 5.0% by weight. This is because when the quantity of addition of the luminescent coloring matter is excessively large, maintenance of the weatherability and durability of the resulting luminescent coloring matter becomes difficult, on the other hand, when the quantity of addition is excessively small, the aforementioned effect of addition of the luminescent coloring matter cannot be achieved adequately.

As the phosphors added to the host material as the guest material, Ir(ppy)₃, Pt(thpy)₂, PtOEP, etc., represented by Chemical formula (11) are used preferably.

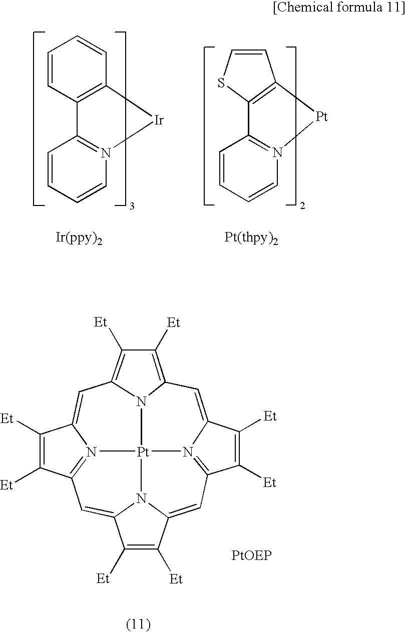

When the phosphors represented by the aforementioned Chemical formula (11) are guest material, especially, CBP, DCTA, and TCPB represented by the Chemical formula (12), and the aforementioned DPVBi and ALq3 are used suitably as the host material.

Both of the aforementioned luminescent coloring matter and the phosphor may be added concurrently to the host material as the guest materials.

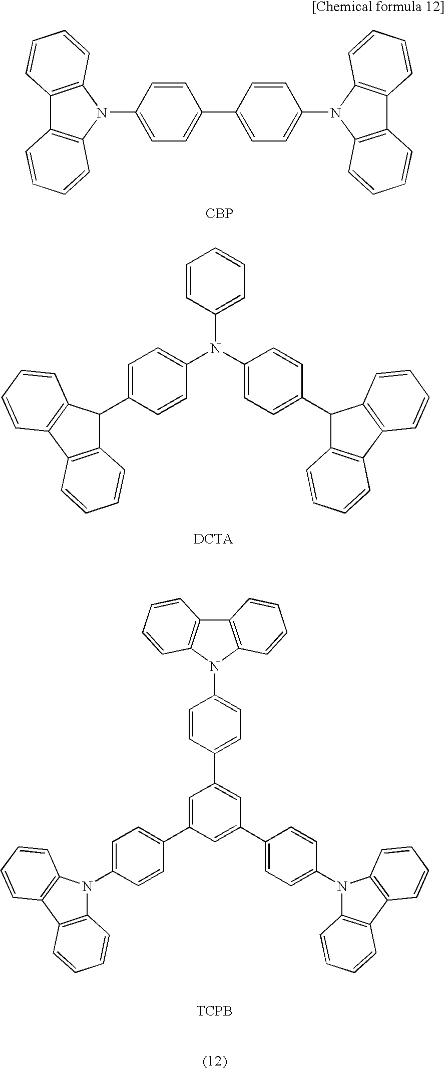

When the luminescent layer 140B of each color (red, green, and blue) is formed from such host/guest-based luminescent materials, initially, the second substrate 11 provided with a material layer made of a host material, and the second substrate 11 provided with a material layer made of a guest material are prepared. Regarding these second substrates, basically the host material is used commonly and, therefore, one sort of second substrate 11 for host material is prepared. On the other hand, three sorts, red, green, and blue, of second substrates 11 are prepared for the guest materials. At that time, regarding these second substrates 11, the material layers thereof may be patterned in advance as shown in FIG. 9(a), or may have a single layer structure as shown in FIG. 6(a).

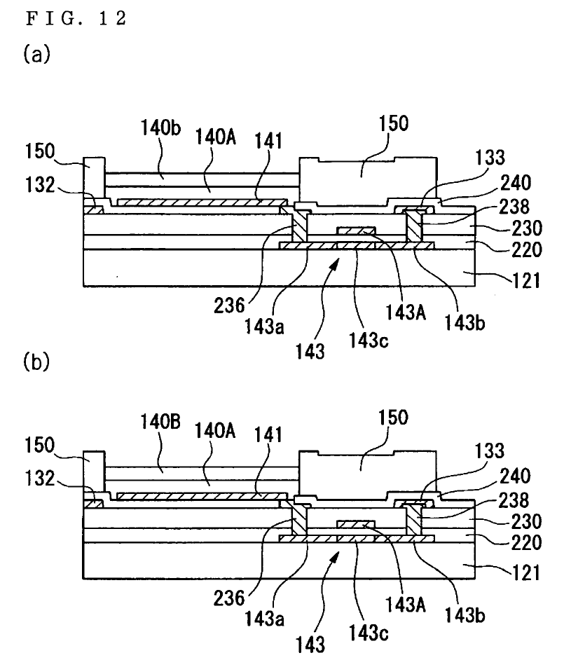

After the second substrates 11 provided with respective material layers are prepared, the second substrate provided with the material layer made of the host material is arranged on the transparent substrate 121, a light beam is applied in a manner similar to that in the first example and, therefore, as shown in FIG. 12(a), a host material layer 140b is formed on the positive hole transport layer 140A in each pixel 1A.

Subsequently, one (for example, for red) of second substrates 11 provided with material layers made of guest materials is arranged in place of this second substrate 11 provided with the material layer made of the host material, the light beam is applied similarly so as to allow the guest material to fly from the material layer, this is allowed to shift and diffuse into the host material layer 140b and, therefore, the aforementioned host material layer 140b is converted to the luminescent layer 140B as shown in FIG. 12(b). Thereafter, in a manner similar to this, the guest materials of the other two colors are irradiated with the light beam and, therefore, are allowed to shift and diffuse into the respective host material layers 140b so as to form the luminescent layers 140B.

At this time, regarding the second substrate 11 provided with the material layer made of the host material, as shown in the aforementioned second example, patterning may be performed beforehand in the flat condition as shown in FIG. 9(a) or patterning may be performed on the convex portion 12 as shown in FIG. 9(b), and subsequently, this may be irradiated with the light beam for patterning. Furthermore, patterning may be performed using the mask 14 for light irradiation as shown in the third example.

Likewise, regarding the second substrate 11 provided with the material layer made of the guest material corresponding to each of the colors, as shown in the aforementioned second example, patterning may be performed beforehand in the flat condition as shown in FIG. 9(a) or patterning may be performed on the convex portion 12 as shown in FIG. 9(b), and subsequently, this may be irradiated with the light beam for patterning. Furthermore, patterning may be performed using the mask 15 for light irradiation as shown in the third example and, in addition, patterning of other colors may be performed sequentially while this is moved.

In particular, regarding the second substrate 11 provided with the material layer made of the guest material, all material layers of respective colors, red, green, and blue, may be patterned on the same second substrate, and each of the guest materials may be added and diffused into the host material layer 140b by one step of light irradiation using this.

When the material layer made of the aforementioned host material or guest material is patterned onto the second substrate 11, preferably, these materials are dissolved or dispersed in solvents so as to produce ink, and this ink is discharged from the aforementioned ink-jet head 30 so as to form the material layer on the second substrate 11.

Specific examples of such solvents include, for example, water, methanol, alcohols compatible with water, e.g., ethanol, organic solvents, e.g., N,N-dimethylformamide (DMF), N-methyl pyrrolidone (NMP), dimethylimidazoline (DMI), and dimethyl sulfoxide (DMSO), and inorganic solvents. At least two of these solvents may be mixed appropriately.

In addition, the aforementioned host material or guest material may contain a wetting agent if necessary and, furthermore, may contain other additives and a coating stabilizer.

Regarding a method in which such a host material and a guest material are patterned (shift of the material) separately and, therefore, the material layer 140B made of these host/guest materials is formed, by shifting separately the guest materials corresponding to red, blue, and green onto respective desired positions of the host material layer 140b formed beforehand, the luminescent layer which emits light with a desired pattern and with desired colors can be formed with ease and with precision. Consequently, this method has advantages in cost and an improvement of efficiency of the step. That is, regarding these host/guest materials, conventionally, patterning was performed by a coevaporation method using a mask, and at that time, it is difficult to separately implant each of colors. In general, this coevaporation is performed using a mask for evaporation. However, since this is evaporation, the material is evaporated to the mask and, therefore, it becomes difficult to use repeatedly the mask many times. Consequently, disadvantages may occur regarding the cost and the improvement of efficiency of the step.

When the host materials are the same in the individual colors, the same host material is applied by coating or evaporation to all over the surface of the transparent substrate 121, the guest material corresponding to the R, G, and B is allowed to shift into the host material by the aforementioned method of the present invention and, therefore, the luminescent layer can be formed as well. When the host materials are the same in the individual colors as described above, the guest material is not specifically patterned, the guest material layer may be formed by a spin coating method, an evaporation method, etc., and thereafter, the luminescent coloring matter may be introduced into the guest material layer by using the method of the present invention.

In the aforementioned first, second, third, and fourth examples, the positive hole transport layer 140A was formed as the layer under the luminescent layer 140B, and the electron transport layer 140C was formed as the layer above the luminescent layer 140B. However, it should be understood that the present invention is not limited to this, and, for example, only one of this positive hole transport layer 140A and the electron transport layer C may be formed, the positive hole injection layer may be formed in place of the positive hole transport layer 140A, and furthermore, only the luminescent layer 140B may be formed alone.

In addition to the aforementioned positive hole injection layer (not shown in the drawing), positive hole transport layer 140A, luminescent layer 140B, and electron transport layer 140C, a whole blocking layer may be formed, for example, on the counter electrode 154 side of the luminescent layer 140B in order to achieve extension of the life of the luminescent layer 140B. As the material for forming such a whole blocking layer, for example, BCP represented by Chemical formula (13) and BAlq represented by Chemical formula (14) is used. However, BAlq is more preferable from the viewpoint of extension of the life.

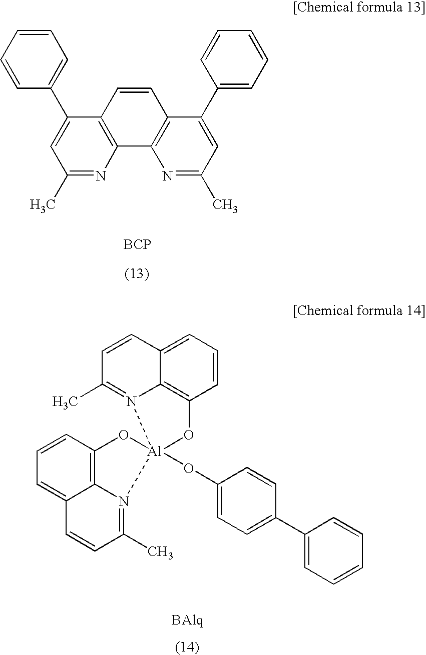

The method for patterning of the present invention is not only applied to formation of the constituent of the organic electroluminescent element shown in the aforementioned example, but also can be applied to various uses. For example, it is possible to apply to formation (patterning) of color filters in various display devices (electro-optic apparatuses), e.g., liquid crystal devices.

That is, for example, the color filter material is applied by coating or patterned by an ink-jet method, and the like, onto the second substrate 11 and, therefore, the material layer 10 is arranged as shown in FIG. 6(a), this second substrate 11 is arranged on the first substrate (a transparent substrate provided with constituents of the display device) in the form shown in FIG. 6(c), the material layer 10 is irradiated with the light beam so as to fly the material, this is thereby shifted onto the first substrate and, therefore, a pattern of the color filter is formed.

Regarding the color filter material used, for example, after inorganic pigment of each color, red, green, and blue, is dispersed in polyurethane oligomer or polymethylmethacrylate oligomer, cyclohexanone and butyl acetate are added as low-boiling point solvents, butyl carbitol acetate is added as a high-boiling point solvent, if necessary, a nonionic surface active agent is further added as a dispersing agent, and the viscosity is adjusted within a predetermined range. The color filter produced from such a material may transmit a desired color, may emit or reflect light of a desired color, and the like.

Regarding a method for manufacturing such a color filter, since the color filter is patterned by the aforementioned method for patterning of the present invention, the color filter can be formed with ease and with precision, and the material for formation thereof can be selected with a high degree of flexibility and, therefore, improvement of the quality of the resulting color filter and reduction of the cost can be achieved.

Regarding a method for manufacturing an electro-optic apparatus in which the color filter is formed by such a method, or each of the constituents in the organic electroluminescent element is formed by the aforementioned method for patterning, the material portion (positive hole transport layer 140A, luminescent layer 140B, electron transport layer 140C, etc.) with a desired pattern or the color filter can be formed with ease and with precision, the materials for formation thereof can be selected with a high degree of flexibility and, therefore, improvement of the quality of the resulting material portion and color filter and, in addition, reduction of the cost can be achieved.

Regarding the electro-optic apparatus thus produced, improvement of the quality of the resulting material portion and color filter and, in addition, reduction of the cost have been achieved, or the luminescent layer which has a desired pattern and which exhibits desired colors is arranged with ease and with precision.

The method for patterning of the present invention can also be applied to methods for manufacturing various electronic apparatuses, and electronic apparatuses produced by this method for manufacture. That is, when at least a part of the constituents of the electronic apparatus is patterned using the method for patterning of the present invention or the patterning apparatus of the present invention, the electronic apparatus of the present invention or the method for manufacturing the same is realized.

Electronic apparatuses to be targeted for application are not specifically limited, and various apparatuses are used. Examples thereof include those having various electronic elements, for example, memories, TFTs (thin film transistors), and diodes.

According to such an electronic apparatus and the method for manufacturing the same, the constituents can be formed with ease and with precision, and the materials for formation thereof can be selected with a high degree of flexibility and, therefore, improvement of the quality and reduction of the cost can be achieved.

Next, specific examples of electronic equipment provided with the electro-optic apparatus using the organic electroluminescent element or the color filter in the aforementioned example will be described.

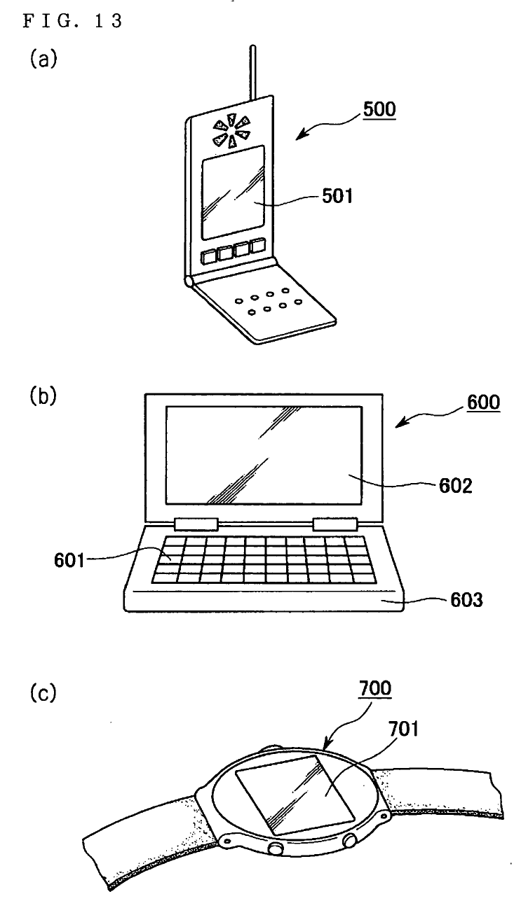

FIG. 13(a) is a perspective view showing an example of a cellular phone. In FIG. 13(a), reference numeral 500 denotes a cellular phone body, and reference numeral 501 denotes a display portion (display means) composed of a display device shown in FIG. 3 and FIG. 4, or a display portion (display means) using the aforementioned color filter.

FIG. 13(b) is a perspective view showing an example of portable information processing apparatuses, for example, word processors and personal computers. In FIG. 13(b), reference numeral 600 denotes an information processing apparatus, reference numeral 601 denotes an input portion, for example, a keyboard, reference numeral 603 denotes an information processing body, and reference numeral 602 denotes a display portion (display means) composed of a display device shown in FIG. 3 and FIG. 4, or a display portion (display means) using the aforementioned color filter.

FIG. 13(c) is a perspective view showing an example of wristwatch type electronic equipments. In FIG. 13(c), reference numeral 700 denotes a watch body, and reference numeral 701 denotes a display portion (display means) composed of a display device shown in FIG. 3 and FIG. 4, or a display portion (display means) using the aforementioned color filter.

The electronic equipments shown in FIGS. 13(a) to (c) are provided with the aforementioned electro-optic apparatus and, therefore, become the electronic equipments provided with the display device capable of exhibiting excellent display quality.

As described above, the method for patterning of the present invention can include the steps of placing a material layer above the first substrate, and irradiating the material layer with the light beam so as to shift the material in the material layer onto the first substrate and to form a material portion with a desired pattern. In this method, the material in the material layer irradiated with the light beam is allowed to shift onto the first substrate based on the principle that when the light beam is applied at high energy, a part of the irradiated material flies molecularly. Consequently, when application of the light beam is performed in accordance with a desired pattern, the material portion with a desired pattern can be formed on the first substrate with ease and with precision. The material in the material layer is not always specifically unlimited, and the flexibility in selection of the material can be increased.

Since the patterning apparatus of the present invention is provided with the light irradiation mechanism for applying the light beam and the holding mechanism for holding the substrate, when the material layer is irradiated with the light beam by the light irradiation mechanism, the material in the material layer can be shifted onto the substrate held by the holding mechanism. Consequently, when application of the light beam is performed in accordance with a desired pattern, the material portion with a desired pattern can be formed on the substrate with ease and with precision. The material in the material layer is not always specifically unlimited, and the flexibility in selection of the material can be increased.

Since the method for manufacturing an organic electroluminescent element of the present invention can include the step of forming at least one of the electron transport layer, the positive hole transport layer, and the luminescent layer by using the aforementioned method for patterning, these electron transport layer, positive hole transport layer, or luminescent layer can be formed with ease and with precision and, furthermore, the material for formation thereof can be selected with a high degree of flexibility. Consequently, improvement of the quality of the resulting organic electroluminescent element and reduction of the cost can be achieved.

Since the method for manufacturing a color filter of the present invention includes the steps of forming the material layer from the color filter material, and patterning the color filter using the aforementioned method for patterning, the color filter can be formed with ease and with precision and, furthermore, the material for formation thereof can be selected with a high degree of flexibility. Consequently, improvement of the quality of the resulting color filter and reduction of the cost can be achieved.

Since the method for manufacturing an electro-optic apparatus of the present invention includes the step of patterning at least a part of constituents by using the aforementioned method for patterning or the method for manufacturing a color filter, the material portion with a desired pattern or the color filter can be formed with ease and with precision and, furthermore, the materials for formation thereof can be selected with a high degree of flexibility. Consequently, improvement of the quality of the resulting material portion and color filter and, in addition, reduction of the cost can be achieved.

Since another method for manufacturing an electro-optic apparatus of the present invention includes the steps of forming beforehand the host material among materials for forming the luminescent layer constituting the organic electroluminescent element on the first substrate with a desired pattern, and thereafter, shifting the guest material in the aforementioned luminescent layer into the pattern made of the aforementioned host material by using the aforementioned method for patterning so as to form the luminescent layer provided with the host material including the guest material, the guest materials corresponding to, for example, red, blue, and green, are separately shifted onto the respective desired positions in the pattern made of the host material, the pattern being formed beforehand, and therefore, the luminescent layer which has a desired pattern and which exhibits desired colors can be formed with ease and with precision.

Since the electro-optic apparatus of the present invention can be produced by the aforementioned method for manufacturing an electro-optic apparatus, improvement of the quality of the resulting material portion and color filter and, furthermore, reduction of the cost can be achieved, or the luminescent layer which has a desired pattern and which exhibits desired colors can be arranged with ease and with precision.

Since the method for manufacturing an electronic apparatus of the present invention includes the step of patterning at least a part of constituents by using the aforementioned method for patterning or the aforementioned patterning apparatus, the constituents can be formed with ease and with precision and, furthermore, the materials for formation thereof can be selected with a high degree of flexibility. Consequently, improvement of the quality of the resulting electronic apparatus and reduction of the cost can be achieved.

Since in an electronic apparatus of the present invention, at least a part of constituents has been patterned by the aforementioned method for patterning or the aforementioned patterning apparatus, the constituents have been formed with ease and with precision and, furthermore, formation has been performed while the materials for formation have been selected with a high degree of flexibility. Consequently, improvement of the quality and reduction of the cost have been achieved.

Since the electronic equipment of the present invention is provided with the aforementioned electro-optic apparatus as a display device, especially regarding the display device, improvement of the quality of the material portion and the color filter produced as described above, and, furthermore, reduction of the cost have been achieved, or the luminescent layer which has a desired pattern and which exhibits desired colors are arranged with ease and with precision.

What is claimed is:

1. A method of patterning, comprising:
providing a first base member including a first film;
placing a second film containing a material above the first film; and
irradiating the second film to shift the material into the first film during a period in which the irradiating of the first film is carried out,
the irradiating of the second film with a light beam including a scanning of a part of the second film.

2. A method of patterning, comprising:
providing a first film that is included in a first base member as a layer;
placing a second film containing a material above the first film; and
irradiating the second film to shift the material into the first film during a period in which the irradiating of the second film is carried out,
the irradiating of the second film with a light beam including a scanning of the light beam.

3. The method according to claim 1, the light beam being a laser beam.

4. The method according to claim 3, the laser beam being a pulsed beam.

5. The method according to claim 1, the light beam inducing a non-linear optical effect.

6. The method according to claim 5, the non-linear optical effect being a multi-photon absorption.

7. The method according to claim 4, the laser beam having a wavelength within an infrared region.

8. A method of manufacturing a film, comprising:
providing a first film that is included in a first base member as a layer;
placing a second film containing a material above the first film; and
irradiating the second film to shift the material into the first film during a period in which the irradiating of the second film is carried out,
the irradiating of the second film with a light beam including a scanning of the light beam.

9. A method of manufacturing an electronic device, comprising:
forming at least one film included in the electronic device by using the method according to claim 8.

10. A method of manufacturing an electronic device, comprising:
providing a first base member including a first film containing a host material;
placing a second film including a guest material above the first film; and
irradiating the second film to shift the material into the first film during a period in which the irradiating of the second film is carried out,
the irradiating of the second film with a light beam including a scanning of the light beam.

11. The method according to claim 10, the guest material being at least one of a fluorescent material and a phosphorescent material.

12. The method according to claim 1, the irradiating of the second film being carried out by irradiating the second film with the light beam through a mask that is formed in accordance with a pattern.

13. The method according to claim 1, the material being used for forming at least one of an electron transport layer, a hole transport layer, and a luminescent layer that constitutes an organic electroluminescent element.

14. A method of manufacturing an organic electroluminescent element, comprising:
forming at least one of an electron transport layer, a hole transport layer, and a luminescent layer that constitutes the organic electroluminescent element by using the method according to claim 12.

15. The method according to claim 1, the material flying into the first film molecularly by the irradiating of the second film.

16. The method according to claim 1, the light beam entering from the first base member.

17. An apparatus for forming a film, comprising:
a light irradiation unit that applies a pulsed light; and
a holding unit that holds a first base member and a second base member,
the apparatus scanning a position of the second base member to be irradiated with the pulsed light.

18. The apparatus according to clam 17, the pulsed light being a laser light.

19. The apparatus according to claim 17, further comprising a movement unit that moves at least one of the first base member and the second base member.

20. The apparatus according to claim 17, the second member being irradiated with the pulsed light, and a material included in the second base member being shifted onto the first base member or into the first base member.
